(19) United States
(12) Patent Application Publication
(10) Pub. No.: US 2026/0013277 A1
(43) Pub. Date: Jan. 8, 2026

(54) LIGHT EMITTING ELEMENT, METHOD OF MANUFACTURING THE LIGHT EMITTING ELEMENT, AND ELECTRONIC DEVICE INCLUDING THE LIGHT EMITTING ELEMENT

(71) Applicant: Samsung Display Co., LTD., Yongin-si (KR)

(72) Inventors: Jun Su PARK, Yongin-si (KR); Hyeong Su CHOI, Yongin-si (KR); Hye Won HONG, Yongin-si (KR); Jung Woon JUNG, Yongin-si (KR)

(73) Assignee: Samsung Display Co., LTD., Yongin-si (KR)

(21) Appl. No.: 19/215,841

(22) Filed: May 22, 2025

(30) Foreign Application Priority Data
Jul. 4, 2024 (KR) 10-2024-0088339

(51) Int. Cl. H10H 20/84; C01B 21/082; C23C 16/36; C23C 16/455; H10H 20/01; H10H 20/825

(52) U.S. Cl. CPC H10H 20/84; C01B 21/0828; C23C 16/36; C23C 16/45553; H10H 20/0137; H10H 20/034; H10H 20/825; C01P 2006/40

(57) ABSTRACT

Provided is a light emitting element including: a light emitting stack member including a first semiconductor layer including a metal nitride doped with a dopant having a first conductivity type, a second semiconductor layer including a metal nitride doped with a dopant having a second conductivity type opposite to the first conductivity type, and an active layer disposed between the first semiconductor layer and the second semiconductor layer; and a first insulative film covering at least a portion of an outer circumferential surface of the light emitting stack member. The first insulative film includes a nitrogen-containing Group IV element oxide. In the nitrogen-containing Group IV element oxide, a content ratio of nitrogen:Group IV element is in a range of about 0.1:1 and about 1:1, based on a unit (atomic %).

### CROSS-REFERENCE TO RELATED APPLICATION

The present application claims priority to and benefits of Korean Patent Application No. 10-2024-0088339 under 35 U.S.C. § 119, filed on Jul. 4, 2024, in the Korean Intellectual Property Office, the entire contents of which are incorporated herein by reference.

### BACKGROUND

### 1. Technical Field

The disclosure generally relates to a light emitting element, a method of manufacturing the light emitting element, and an electronic device including the light emitting element.

### 2. Description of the Related Art

A display device includes light emitting elements. The light emitting elements emit lights, and the display device displays an image by combining the lights emitted from the light emitting elements. In case that the efficiency of the light emitting elements is improved, the display quality of the display device can be improved.

### SUMMARY

Embodiments provide a light emitting element having improved efficiency and a method of manufacturing the light emitting element.

In accordance with an aspect of the disclosure, there is provided a light emitting element including: a light emitting stack member including a first semiconductor layer including a metal nitride doped with a dopant having a first conductivity type, a second semiconductor layer including a metal nitride doped with a dopant having a second conductivity type opposite to the first conductivity type, and an active layer disposed between the first semiconductor layer and the second semiconductor layer; and a first insulative film covering at least a portion of an outer circumferential surface of the light emitting stack member, wherein the first insulative film includes a nitrogen-containing Group IV element oxide, and wherein, in the nitrogen-containing Group IV element oxide, a content ratio of nitrogen:Group IV element is in a range of about 0.1:1 to about 1:1, based on a unit (atomic %).

The first insulative film may be in direct contact with at least one of the first semiconductor layer and the second semiconductor layer.

The first insulative film may cover all side surfaces of the first and second semiconductor layers, which define a side surface of the light emitting stack member.

The nitrogen-containing Group IV element oxide may further include carbon (C).

In the nitrogen-containing Group IV element oxide, a content ratio of carbon:Group IV element may be in a range of about 0.01:1 to about 1.3:1, based on a unit (atomic %).

In the nitrogen-containing Group IV element oxide, a content ratio of oxygen:Group IV element may be in a range of about 1.5:1 to about 2.5:1, based on a unit (atomic %).

A Group IV element included in the nitrogen-containing Group IV element oxide may be zirconium (Zr) or hafnium (Hf).

The light emitting element may further include a second insulative film covering the first insulative film.

At least the first insulative film may be disposed between the second insulative film and the light emitting stack member.

The second insulative film may include at least one selected from the group consisting of silicon oxide, silicon nitride, silicon oxynitride, aluminum oxide, and titanium oxide.

In accordance with another aspect of the disclosure, there is provided a method of manufacturing a light emitting element, the method including forming a first insulative film covering at least a portion of an outer circumferential surface of a light emitting stack member, wherein the light emitting stack member includes a first semiconductor layer including a metal nitride doped with a dopant having a first conductivity type, a second semiconductor layer including a metal nitride doped with a dopant having a second conductivity type opposite to the first conductivity type, and an active layer disposed between the first semiconductor layer and the second semiconductor layer, wherein the first insulative film includes a nitrogen-containing Group IV element oxide, and wherein, in the nitrogen-containing Group IV element oxide, a content ratio of nitrogen:Group IV element is in a range of about 0.1:1 to about 1:1, based on a unit (atomic %). The first insulative film may be formed through an atomic layer deposition process using a Group IV element-amine-based compound precursor represented by the following Chemical Formula 1:

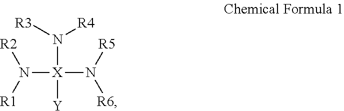

in the Chemical Formula 1, each of R1 to R6 is independently hydrogen or an alkyl group of C1 to C2, and R1 to R6 cannot all be hydrogen;
X is a Group IV element; and
Y is an amino group, an amine group in which at least one of hydrogen atoms of the amino group is replaced with an alkyl group of C1 to C2, or an aryl group of C5 to C6.

The X may be zirconium (Zr) or hafnium (Hf).

The Chemical Formula 1 may be represented by the following Chemical Formula 2 or the following Chemical Formula 3:

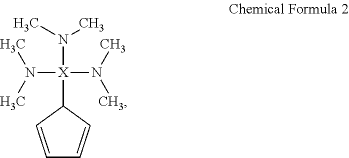

in the Chemical Formula 2, X is a Group IV element, and

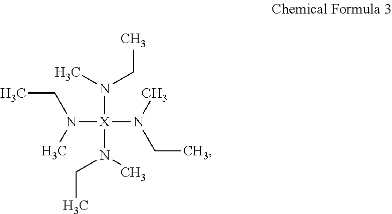

in the Chemical Formula 3, X is a Group IV element.

The atomic layer deposition process may be performed in a range of about 50° C. and about 200° C.

The first insulative film may be in direct contact with at least one of the first semiconductor layer and the second semiconductor layer.

The first insulative film may cover all side surfaces of the first and second semiconductor layers, which define a side surface of the light emitting stack member.

According to an embodiment of the disclosure, an electronic device may include a display device including a light emitting element disposed on a substrate, wherein the light emitting element includes: a light emitting stack member including a first semiconductor layer including a metal nitride doped with a dopant having a first conductivity type, a second semiconductor layer including a metal nitride doped with a dopant having a second conductivity type opposite to the first conductivity type, and an active layer disposed between the first semiconductor layer and the second semiconductor layer; and a first insulative film covering at least a portion of an outer circumferential surface of the light emitting stack member. The first insulative film may include a nitrogen-containing Group IV element oxide. In the nitrogen-containing Group IV element oxide, a content ratio of nitrogen:Group IV element may be in a range of about 0.1:1 to about 1:1, based on a unit (atomic %).

The first insulative film may be in direct contact with at least one of the first semiconductor layer and the second semiconductor layer.

The first insulative film may cover all side surfaces of the first and second semiconductor layers, which define a side surface of the light emitting stack member.

The nitrogen-containing Group IV element oxide may further include carbon (C).

In the nitrogen-containing Group IV element oxide, a content ratio of carbon:Group IV element may be in a range of about 0.01:1 to about 1.3:1, based on a unit (atomic %).

In the nitrogen-containing Group IV element oxide, a content ratio of oxygen:Group IV element may be in a range of about 1.5:1 to about 2.5:1, based on a unit (atomic %).

A Group IV element included in the nitrogen-containing Group IV element oxide may be zirconium (Zr) or hafnium (Hf).

The electronic device may be at least one of a smart watch, a mobile phone, a smartphone, a portable computer, a tablet personal computer (PC), a watch phone, an automotive display, a smart glass, a portable multimedia player (PMP), a navigation system, an ultra-mobile computer (UMPC), a head mounted display (HMD) device, a virtual reality (VR) device, a mixed reality (MR) device, and an augmented reality (AR) device.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that in case that an element is referred to as being “between” two elements, it can be the only element between the two elements, or one or more intervening elements may also be present. Like reference numerals refer to like elements throughout.

FIG. 1 is a schematic plan view illustrating a light emitting element in accordance with embodiments of the disclosure.

FIG. 2 is a schematic sectional view taken along line I1-I1′ shown in FIG. 1.

FIGS. 3 and 4 are schematic views illustrating an effect according to a content of nitrogen included in a first insulative film in contact with a semiconductor layer.

FIGS. 5 to 9 are schematic sectional views illustrating a method of manufacturing the light emitting element shown in FIG. 1.

FIG. 10 is a schematic block diagram illustrating a display device in accordance with an embodiment of the disclosure.

FIG. 11 is a schematic block diagram illustrating any one sub-pixel among sub-pixels included in the display device shown in FIG. 10.

FIG. 12 is a schematic plan view illustrating a display panel constituting the display device shown in FIG. 10.

FIG. 13 is a schematic sectional view illustrating an embodiment of the display panel shown in FIG. 12.

FIG. 14 is a schematic sectional view illustrating another embodiment of the display panel shown in FIG. 12.

FIG. 15 is a schematic plan view illustrating an embodiment of any one pixel among pixels included in the display panel shown in FIG. 12.

FIG. 16 is a schematic sectional view taken along line X1-X1′ shown in FIG. 15.

FIG. 17 is a schematic block diagram illustrating a display system in accordance with an embodiment of the disclosure.

FIGS. 18 to 21 are schematic perspective views illustrating application examples of the display system.

FIG. 22 illustrates schematic graphs showing an XPS result of a first insulative film of Embodiment 1.

FIG. 23 illustrates schematic graphs showing an XPS result of a first insulative film of Embodiment 2.

FIG. 24 illustrates schematic graphs showing an XPS result of a first insulative film of Embodiment 3.

FIG. 25 illustrates schematic graphs showing an XPS result of a first insulative film of Embodiment 4.

FIG. 26 illustrates schematic graphs showing an XPS result of a first insulative film of Comparative Example 1.

FIG. 27 illustrates schematic graphs showing an XPS result of a first insulative film of Comparative Example 2.

### DETAILED DESCRIPTION OF THE EMBODIMENTS

Hereinafter, embodiments of the disclosure will be described in more detail with reference to the accompanying drawings. In the description below, only a desirable part to understand an operation according to the disclosure is described and the descriptions of other parts are omitted in order not to unnecessarily obscure subject matters of the disclosure. The disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, in case that an element is referred to as being “connected” or “coupled” to another element, it can be directly connected or coupled to the another element or be indirectly connected or coupled to the another element with one or more intervening elements disposed therebetween. The technical terms used herein are used only for the purpose of illustrating a specific embodiment and not intended to limit the embodiment. It will be understood that in case that a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

The embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

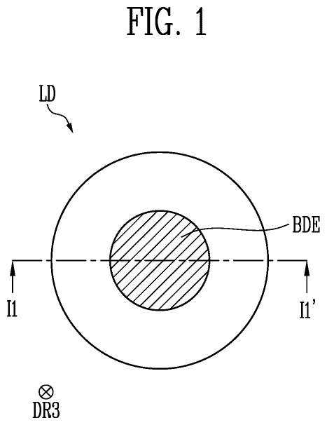

A light emitting element of the disclosure will be described with reference to FIGS. 1 to 4.

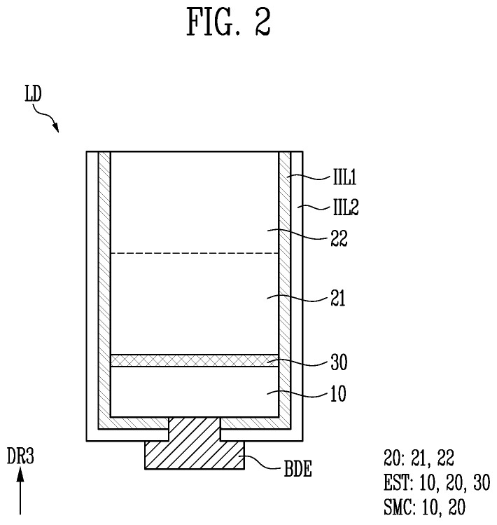

FIG. 1 is a schematic plan view illustrating a light emitting element in accordance with embodiments of the disclosure. FIG. 2 is a schematic sectional view taken along line I1-I1′ shown in FIG. 1.

Referring to FIGS. 1 and 2, the light emitting element LD may include a light emitting stack structure EST, a first insulative film IIL1, a second insulative film IIL2, and a bonding electrode BDE. The light emitting stack structure EST may include a semiconductor layer SMC and an active layer 30. The semiconductor layer SMC may include a first semiconductor layer 10 and a second semiconductor layer 20.

The first semiconductor layer 10 may provide holes. The first semiconductor layer 10 may include a metal nitride doped with a dopant having a first conductivity type. For example, the first semiconductor layer 10 may include at least one p-type semiconductor layer. For example, the first semiconductor layer 10 may include at least one semiconductor material among gallium nitride (GaN), aluminum gallium nitride (AlGaN), indium gallium nitride (InGaN), aluminum nitride (AlN), and indium nitride (InN), and be a p-type semiconductor layer doped with a dopant having a first conductivity type (or a p-type dopant), such as magnesium (Mg), zinc (Zn), calcium (Ca), strontium (Sr) or barium (Ba). However, the material constituting the first semiconductor layer 10 is not limited thereto. Various materials may constitute the first semiconductor layer 10. The first semiconductor layer 10 may include a gallium nitride (GaN) semiconductor material doped with the dopant having the first conductivity type (or the p-type dopant).

The second semiconductor layer 20 may be disposed on the first semiconductor layer 10. The second semiconductor layer 20 may include a metal nitride doped with a dopant having a second conductivity type opposite to the conductivity type. For example, the second semiconductor layer 20 may include at least one n-type semiconductor layer. For example, the second semiconductor layer 20 may include any one semiconductor material among gallium nitride (GaN), aluminum gallium nitride (AlGaN), indium gallium nitride (InGaN), aluminum nitride (AlN), and indium nitride (InN), and be an n-type semiconductor layer doped with a dopant having a second conductivity type (or an n-type dopant), such as silicon (Si), germanium (Ge) or tin (Sn). However, the material constituting the second semiconductor layer 20 is not limited thereto. Various materials may constitute the second semiconductor layer 20. The second semiconductor layer 20 may include a gallium nitride (GaN) semiconductor material doped with the dopant having the second conductivity type (or the n-type dopant).

The second semiconductor layer 20 may include a first doping portion 21 and a second doping portion 22, which are sequentially stacked in a third direction DR3 (e.g., thickness direction). The first doping portion 21 may be a region in which a dopant is doped at a relatively high concentration. The second doping portion 22 may be a region in which the dopant is doped at a relatively low concentration or a region in which the dopant is not substantially doped. For example, a first average doping concentration in the first doping portion 21 may be greater than a second average doping concentration in the second doping portion 22. The first doping portion 21 and the second doping portion 22 may be integrally formed, to define the second semiconductor layer 20.

The active layer 30 may be disposed between the first semiconductor layer 10 and the second semiconductor layer 20 in the third direction DR3. The active layer 30 may provide a region in which electrons and holes are recombined. As electrons and holes are recombined in the active layer 30, light may be generated, which has a level changed to a low energy level and has a wavelength corresponding to the low energy level. The active layer 30 may be formed in a single quantum well structure or a multi-quantum well structure. In case that the active layer 30 is formed in the multi-quantum well structure, a unit including a barrier layer, a strain reinforcing layer, and a well layer may be repeatedly stacked, to form the active layer 30. However, the active layer 30 is not limited to the above-described structure.

The light emitting stack structure EST may have a pillar shape in which the first semiconductor layer 10, the active layer 30, and the second semiconductor layer 20 are stacked in the third direction DR3. For example, the light emitting stack structure EST may have a circular pillar shape or a polygonal pillar shape. However, the shape of the light emitting stack structure EST is not limited thereto.

The bonding electrode BDE may be disposed under the first semiconductor layer 10. The bonding electrode BDE may be electrically connected to the first semiconductor layer 10. The bonding electrode BDE may include, for example, a eutectic metal. In another embodiment, the bonding electrode BDE may be omitted.

The first insulative film IIL1 may directly cover at least a portion of an outer circumferential surface of the light emitting stack structure EST. For example, the first insulative film IIL1 may directly cover a side (e.g., circumferential) surface of the light emitting stack structure EST and a portion of a bottom surface of the light emitting stack structure EST. The first insulative film IIL1 may prevent an electrical short circuit which may occur while the active layer 10 is in contact with another conductive material except the first and second semiconductor layers 10 and 20. The first insulative film IIL1 may expose a top surface of the light emitting stack structure EST.

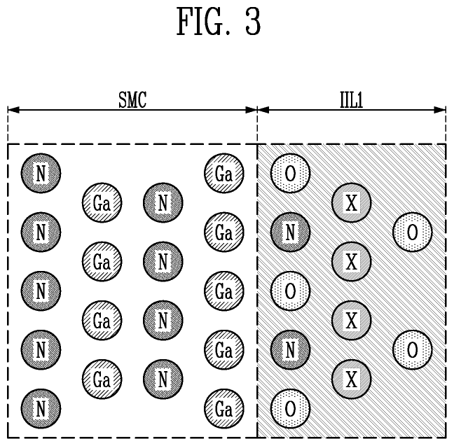

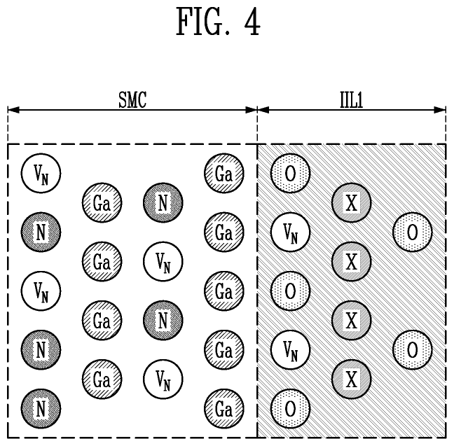

The first insulative film IIL1 may include a nitrogen-containing Group IV element oxide. In the nitrogen-containing Group IV element oxide, a content ratio of nitrogen:Group IV element may be about 0.1:1 or more and about 1:1 or less, based on a unit (atomic %). In case that a content of nitrogen satisfies the above-described numerical range, the first insulative film IIL1 can effectively perform a function of suppressing nitrogen vacancy formation at surfaces of the first and second semiconductor layers 10 and 20. This will be described later with reference to FIGS. 3 and 4. In case that the content of nitrogen satisfies the above-described numerical range, the first insulative film IIL1 having excellent film quality can be provided. For example, film quality deterioration caused by an excessive nitrogen content in the first insulative film IIL1 can be prevented.

The first insulative film IIL1 may be in direct contact with at least one of the first semiconductor layer 10 and the second semiconductor layer 20. The first insulative film IIL1 may cover (e.g., directly cover) all side surfaces of the first and second semiconductor layers 10 and 20 defining the side surface of the light emitting stack structure EST. Accordingly, the nitrogen vacancy formation at the side surfaces of the first and second semiconductor layers 10 and 20 can be effectively suppressed by the first insulative film IIL1 containing nitrogen.

The nitrogen-containing Group IV element oxide may further include carbon (C). In the nitrogen-containing Group IV element oxide, a content ratio of carbon:Group IV element may be about 0.01:1 or more and about 1.3:1 or less, based on a unit (atomic %). In case that a content of carbon satisfies the above-described numerical range, the conductivity of the first insulative film IIL1 can be maintained sufficiently low. Accordingly, a leakage current can be prevented from being generated through the first insulative film IIL1.

In the nitrogen-containing Group IV element oxide, a content ratio of oxygen:Group IV element may be about 1.5:1 or more and about 2.5:1 or less, based on a unit (atomic %).

The Group IV element included in the nitrogen-containing Group IV element oxide may be zirconium (Zr) or hafnium (Hf). Zirconium oxide and hafnium oxide may have a relatively high dielectric constant (e.g., may have a dielectric constant about four times higher than a dielectric constant of silicon oxide), and may have excellent thermal stability. Thus, the first insulative film IIL1 including the zirconium oxide and the hafnium oxide can have excellent reliability as an insulative film.

The second insulative film IIL2 may cover the outer surface of the first insulative film IIL1. The second insulative film IIL2 may not in direct contact with the light emitting stack structure EST. For example, at least the first insulative film IIL1 may be disposed between the second insulative film IIL2 and the light emitting stack structure EST.

The second insulative film IIL2 may include a transparent insulating material. For example, the second insulative film IIL2 may include at least one selected from the group consisting of silicon oxide, silicon nitride, silicon oxynitride, aluminum oxide, and titanium oxide.

In another example, the second insulative film IIL2 may be omitted.

FIGS. 3 and 4 are schematic views illustrating an effect according to a content of nitrogen included in the first insulative film in contact with the semiconductor layer.

In FIGS. 3 and 4, the semiconductor layer SMC and a portion of the first insulative film IIL1 covering (e.g., directly covering) the semiconductor layer SMC are illustrated. The semiconductor layer SMC may be understood as any one of the first and second semiconductor layers 10 and 20, and the following description may be substantially equally applied to both the first and second semiconductor layers 10 and 20.

FIG. 3 is a schematic view illustrating an embodiment in which the content of nitrogen in the nitrogen-containing Group IV element oxide included in the first insulative film IIL1 satisfies the above-described numerical range (the content ratio of nitrogen:Group IV element is about 0.1:1 or more and about 1:1 or less, based on a unit (atomic %)), and FIG. 4 is a view illustrating an embodiment in which the content of nitrogen in the nitrogen-containing Group IV element oxide included in the first insulative film IIL1 fails to reach the above-described numerical range.

Referring to FIG. 3, as the content of nitrogen of the first insulative film IIL1 satisfies the above-described numerical range, a nitrogen vacancy may not substantially exist at a surface of the semiconductor layer SMC, which is adjacent to the first insulative film IIL1. Thus, the efficiency of the light emitting element LD can be improved.

On the other hand, referring to FIG. 4, the content of nitrogen of the first insulative film IIL1 may fail to reach the above-described numerical range. For example, in the Group IV element oxide the content ratio of nitrogen:Group IV element is about 0:1 or more and less than about 0.1:1, based on a unit (atomic %) (i.e., the first insulative film IIL1 may include no nitrogen or include nitrogen in a relatively small content). A nitrogen vacancy V_{N} may exist at a surface of the semiconductor layer SMC, which is adjacent to the first insulative film IIL1. A dangling bond may be formed in a region adjacent to the nitrogen vacancy V_{N}. The nitrogen vacancy V_{N} and the dangling bond formed according thereto may cause a carrier (e.g., hole or electron) trap in the semiconductor layer SMC. Therefore, the efficiency of the light emitting element LD may be deteriorated.

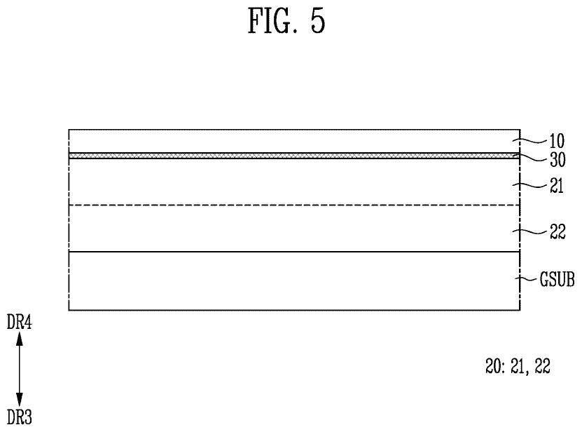

A method of manufacturing the light emitting element of the disclosure will be described with reference to FIGS. 5 to 9. In FIGS. 5 to 9, descriptions of portions overlapping the portions which have been described with reference to FIGS. 1 to 4 will be omitted.

FIGS. 5 to 9 are schematic sectional views illustrating a method of manufacturing the light emitting element shown in FIG. 1.

Referring to FIG. 5, a stacked substrate GSUB may be prepared (or provided), and a second semiconductor layer 20, an active layer 30, and a first semiconductor layer 10 may be sequentially formed on the stacked substrate GSUB in a fourth direction DR4 opposite to the third direction DR3.

The stacked substrate GSUB may be a base substrate for stacking a target material. The stacked substrate GSUB may be a wafer for epitaxial growth on a predetermined material. The stacked substrate GSUB may be any one of a sapphire substrate, a GaAs substrate, a Ga substrate, and an InP substrate. However, the stacked substrate GSUB is not limited thereto. For example, in case that a specific material satisfies a selectivity for manufacturing the light emitting element LD, and the epitaxial growth on the predetermined material can be smoothly made, the specific material may be selected as a material of the stacked substrate GSUB.

The second semiconductor layer 20, the active layer 30, and the first semiconductor layer 10 may be formed by any one method among metal organic chemical vapor-phase deposition, molecular beam epitaxy, vapor phase epitaxy, and liquid phase epitaxy.

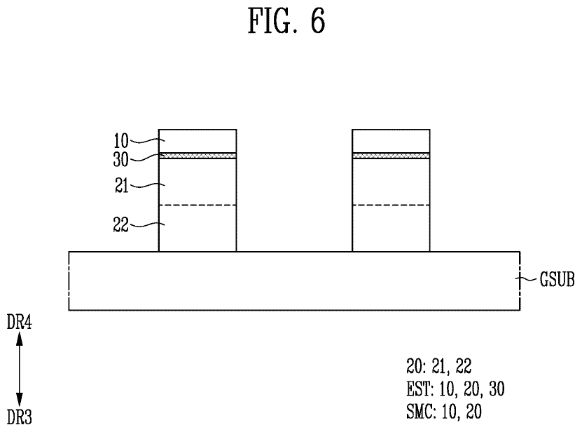

Referring to FIG. 6, at least a portion of each of the first semiconductor layer 10, the second semiconductor layer 20, and the active layer 30 may be removed, thereby forming a light emitting stack structure EST. The light emitting stack structure EST may be formed in plurality, and multiple light emitting stack structures EST may be spaced apart from each other.

An etching process on the first semiconductor layer 10, the second semiconductor layer 20, and the active layer 30 may be performed. In order to form the light emitting stack structures EST individually separated from each other, a mask (not shown) may be disposed in a structure in which the second semiconductor layer 20, the active layer 30, and the first semiconductor layer 10 are sequentially stacked in the fourth direction DR4, and patterning at a distance of nano scale or micro scale may be performed by performing an etching process. The etching process may be performed in the third direction DR3.

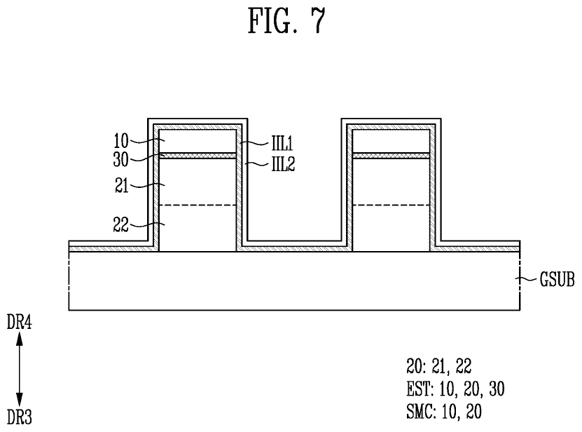

In the etching process, the nitrogen vacancy V_{N} which has been described with reference to FIG. 4 may be formed at a side surface of the light emitting stack structure EST, which is exposed to etching particles and the like. The nitrogen vacancy V_{N} may cause deterioration of the efficiency of the light emitting element LD. Therefore, it is desirable to effectively suppress the nitrogen vacancy V_{N}, and this will be described with reference to FIG. 7.

Referring to FIG. 7, after a first insulative film IIL1 is formed, a second insulative film IIL2 may be formed. The first and second insulative films IIL1 and IIL2 may be formed (e.g., entirely formed). Therefore, the first insulative film IIL1 may be provided to directly cover the entire outer circumferential surface of the light emitting stack structure EST except a bottom surface of the light emitting stack structure EST, which is in contact with the stacked substrate GSUB. The second insulative film IIL2 may be provided to directly cover the outer surface of the first insulative film IIL1.

As has been described with reference to FIGS. 1 to 4, the first insulative film IIL1 may include the nitrogen-containing Group IV element oxide. In the nitrogen-containing Group IV element oxide, the content ratio of nitrogen:Group IV element may be about 0.1:1 or more and about 1:1 or less, based on a unit (atomic %). The second insulative film IIL2 may include a transparent insulative material. For example, the second insulative film IIL2 may include at least one selected from the group consisting of silicon oxide, silicon nitride, silicon oxynitride, aluminum oxide, and titanium oxide.

The first insulative film IIL1 may be formed through atomic layer deposition using a Group IV element-amine-based compound precursor represented by the following Chemical Formula 1. Accordingly, a nitrogen radical derived from the Group IV element-amine-based compound precursor may fill the nitrogen vacancy V_{N} (refer FIG. 4) formed by the etching process which has described with reference to FIG. 6. Thus, the nitrogen vacancy V_{N} can be effectively suppressed, and accordingly, the efficiency of the light emitting element LD can be improved.

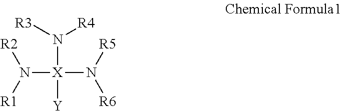

In the Chemical Formula 1, each of R1 to R6 is independently hydrogen or an alkyl group of C1 to C2, and R1 to R6 cannot all be hydrogen;
X is a Group IV element; and
Y is an amino group, an amine group in which at least one of hydrogen atoms of the amino group is replaced with an alkyl group of C1 to C2, or an aryl group of C5 to C6.

The Chemical Formula 1 may be represented by the following Chemical Formula 2 or the following Chemical Formula 3. A compound represented by the following Chemical Formula 2 may be, for example, tris(dimethylamino)cyclopentadienyl zirconium (CAS number: 33271-88-4). A compound represented by the following Chemical Formula 3 may be, for example, tetrakis(ethylmethylamido)zirconium (CAS number: 175923-04-3). However, the compound represented by the following Chemical Formula 2 or the compound represented by the following Chemical Formula 3 is not limited thereto.

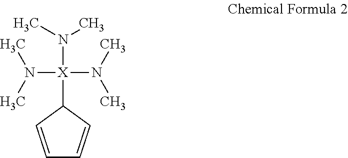

In the Chemical Formula 2, X is a Group IV element.

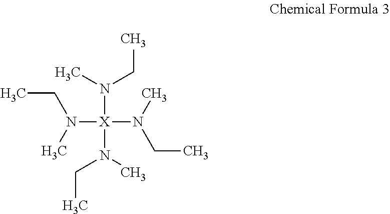

In the Chemical Formula 3, X is a Group IV element.

The X may be zirconium (Zr) or hafnium (Hf). Since the thermal stability and volatility of the Group IV element-amine-based compound precursor are excellent, the atomic layer deposition process using the Group IV element-amine-based compound precursor can be efficiently performed.

The atomic layer deposition process using the Group IV element-amine-based compound precursor may be performed at about 50° C. or higher and about 200° C. or lower.

The content of nitrogen in the nitrogen-containing Group IV element oxide included in the first insulative film IIL1 may be provided to satisfy the above-described numerical range (the content ratio of nitrogen:Group IV element is about 0.1:1 or more and about 1:1 or less, based on a unit (atomic %)). For example, in case that the atomic layer deposition process is performed at a temperature which is less than the above-described temperature range, the formation of the first insulative film IIL1 may be substantially impossible due to that a sufficient temperature for performing atomic layer deposition is not provided. For example, in case that the atomic layer deposition process is performed at a temperature exceeding the above-described temperature range, the nitrogen radical derived from the Group IV element-amine-based compound precursor is excessively volatilized, and therefore the content of nitrogen of the first insulative film IIL1 may fail to reach the above-described numerical range.

The Group IV element-amine-based compound precursor used in the atomic layer deposition process may include carbon. Therefore, the first insulative film IIL1 formed through the atomic layer deposition process may include carbon derived from the Group IV element-amine-based compound precursor. As the first insulative film IIL1 includes carbon, the first insulative film IIL1 may have conductivity having a level roughly in proportion to the content of carbon included in the first insulative film IIL1. In the first insulative film IIL1, the content ratio of carbon:Group IV element may be about 0.01:1 or more and about 1.3:1 or less, based on a unit (atomic %). Accordingly, the conductivity of the first insulative film IIL1 is maintained at a sufficiently low level so that a leakage current through the first insulative film IIL1 is not substantially generated.

A precursor for providing oxygen may be used together with the Group IV element-amine-based compound precursor. Accordingly, the first insulative film IIL1 may be provided to include a Group IV element oxide.

The method of forming the second insulative film IIL2 may not be particularly limited. In order to form the second insulative film IIL2, various methods previously known in the art may be used with limitation. For example, the second insulative film IIL2 may be formed (e.g., entirely formed) through an atomic layer deposition process.

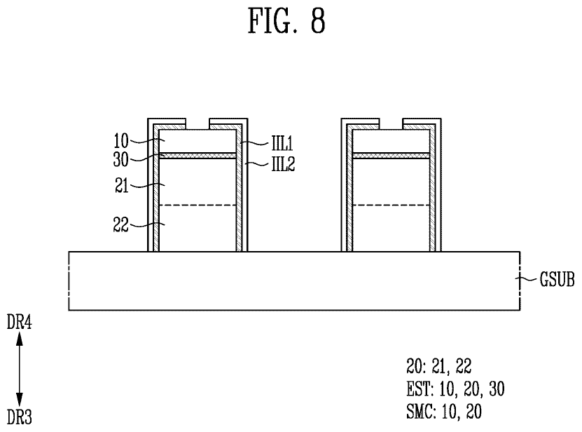

Referring to FIG. 8, portions of the first insulative film IIL1 and the second insulative film IIL2 may be removed. Accordingly, the first and second insulative films IIL1 and IIL2 having the shapes which have been described with reference to FIG. 2 may be provided.

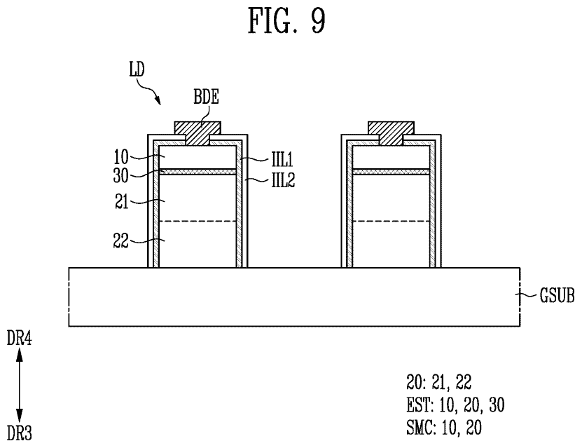

Referring to FIG. 9, a bonding electrode BDE may be formed. The bonding electrode BDE may be electrically connected to the first semiconductor layer 10. For example, the bonding electrode BDE may be electrically in contact with the first semiconductor layer 10 through a penetration hole formed in the first and second insulative films IIL1 and IIL2. Accordingly, a light emitting element LD may be formed on the stacked substrate GSUB.

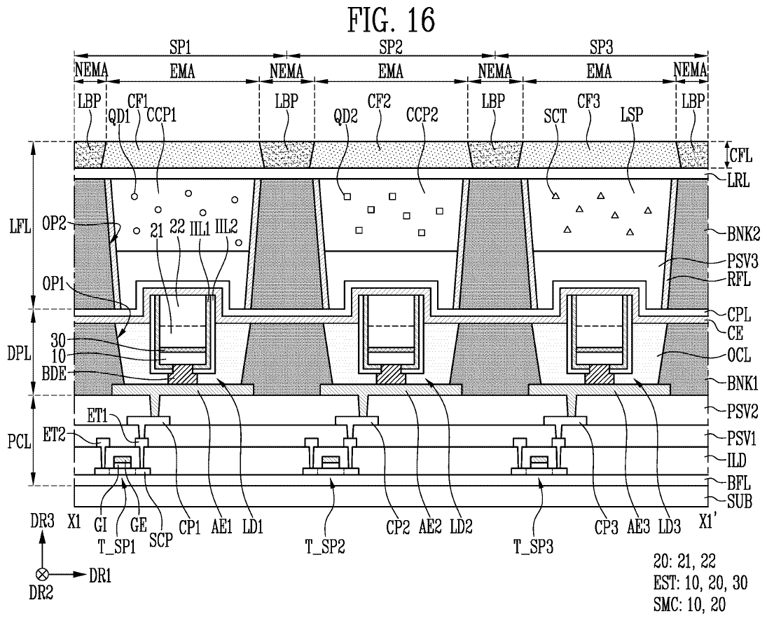

After this step, the light emitting element LD formed on the stacked substrate GSUB may be provided in the display device DD. For example, the light emitting element LD may be separated from the stacked substrate GSUB. The separated light emitting element LD may be provided on an electrode (e.g., AE1, AE2, and AE3 shown in FIG. 16) of the display device DD through various methods previously known in the art.

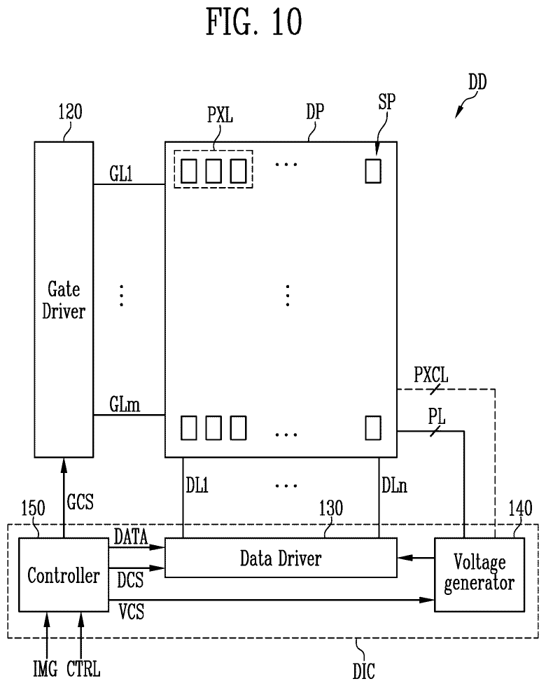

An embodiment of a display device to which the light emitting element of the disclosure is applied will be described with reference to FIGS. 10 to 16.

FIG. 10 is a schematic block diagram illustrating a display device in accordance with an embodiment of the disclosure.

Referring to FIG. 10, the display device DD may include a display panel DP, a gate driver 120, a data driver 130, a voltage generator 140, and a controller 150.

The display panel DP may include sub-pixels SP. The sub-pixels SP may be electrically connected to the gate driver 120 through first to mth gate lines GL1 to GLm. The sub-pixels SP may be electrically connected to the data driver 130 through first to nth data lines DL1 to DLn.

The sub-pixels SP may generate lights of two or more colors. For example, each of the sub-pixels SP may generate lights of red, green, blue, cyan, magenta, yellow, white, and the like.

Two or more sub-pixels among the sub-pixels SP may constitute a pixel PXL. For example, the pixel PXL may include three sub-pixels as depicted in FIG. 10. The pixel PXL may emit lights of various colors with various luminances according to a combination of lights emitted from the sub-pixels included in the pixel PXL.

The gate driver 120 may be electrically connected to the sub-pixels SP arranged in a row direction through the first to mth gate lines GL1 to GLm. The gate driver 120 may output gate signals to the first to mth gate lines GL1 to GLm in response to a gate control signal GCS. The gate control signal GCS may include a start signal indicating a start of each frame, a horizontal synchronization signal, and the like.

The gate driver 120 may be disposed at one side of the display panel DP. However, embodiments are not limited thereto. For example, the gate driver 120 may be divided into two or more drivers which are physically and/or logically divided, and these drivers may be disposed at one side of the display panel DP and the other side of the display panel DP, which is opposite to the one side. As such, in some embodiments, the gate driver 120 may be disposed in various forms at the periphery of the display panel DP.

The data driver 130 may be electrically connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. The data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to nth data lines DL1 to DLn by using the received voltages. In case that a gate signal is applied to each of the first to mth gate lines GL1 to GLm, data signals corresponding to the image data DATA may be applied to the first to nth data line DL1 to DLm. Accordingly, corresponding sub-pixels SP may generate light corresponding to the data signals, and the display panel DP may display an image.

The gate driver 120 and the data driver 130 may include complementary metal-oxide semiconductor (CMOS) circuit elements.

The voltage generator 140 may operate in response to a voltage control signal VCS from the controller 150. The voltage generator 140 may generate multiple voltages and provide the generated voltages to components of the display device DD. The voltage generator 140 may generate multiple voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a predetermined reference voltage may be applied to the first to nth data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. The voltage generator 140 may provide the pixel control signals to the sub-pixels SP through pixel control lines PXCL. As depicted in FIG. 10, it is illustrated that the pixel control lines PXCL are electrically connected between the voltage generator 140 and the display panel DP. However, embodiments are not limited thereto. For example, the pixel control lines PXCL may be electrically connected between the gate driver 120 and the display panel DP. The pixel control signals may be transferred to the pixel control lines PXCL through the gate driver 120 from the voltage generator 140.

The controller 150 may control overall operations of the display device DD. The controller 150 may receive, from an external source, an input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. The controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As depicted in FIG. 10, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

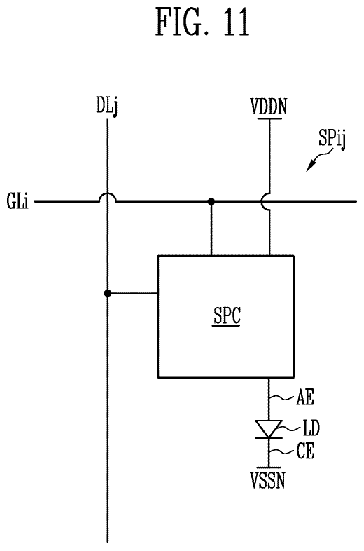

FIG. 11 is a schematic block diagram illustrating any one sub-pixel among the sub-pixels included in the display device shown in FIG. 10. As depicted in FIG. 11, a sub-pixel SPij arranged on an ith row (i is an integer greater than or equal to 1 and smaller than or equal to m) and a jth column (j is an integer greater than or equal to 1 and smaller than or equal to n) among the sub-pixels SP shown in FIG. 10 is illustrated.

Referring to FIG. 11, the sub-pixel SPij may include a sub-pixel circuit SPC and a light emitting element LD.

The light emitting element LD may be electrically connected between a first power voltage node VDDN and a second power voltage node VSSN. The first power voltage node VDDN may be electrically connected to one of the power lines PL shown in FIG. 10, to receive a first power voltage. The second power voltage node VSSN may be electrically connected to another of the power lines PL, to receive a second power voltage. The first power voltage may have a voltage level higher than a voltage level of the second power voltage.

The light emitting element LD may be electrically connected between an anode electrode AE and a cathode electrode CE. The anode electrode AE may be electrically connected to the first power voltage node VDDN through the sub-pixel circuit SPC. For example, the anode electrode AE may be electrically connected to the first power voltage node VDDN through one or more transistors included in the sub-pixel circuit SPC. The cathode electrode CE may be electrically connected to the second power voltage node VSSN. The light emitting element LD may emit light according to a current flowing from the anode electrode AE to the cathode electrode CE.

The sub-pixel circuit SPC may be electrically connected to an ith gate line GLi among the first to mth gate lines GL1 to GLm shown in FIG. 10 and a jth data line DLj among the first to nth data lines DL1 to DLn shown in FIG. 10. In response to a gate signal received through the ith gate line GLi, the sub-pixel circuit SPC may control the light emitting element LD to emit light according to a data signal received through the jth data line DLj. The sub-pixel circuit SPC may be further electrically connected to the pixel control lines PXCL shown in FIG. 10. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The transistors of the sub-pixel circuit SPC may include P-type transistors and/or N-type transistors. The transistors of the sub-pixel circuit SPC may include a Metal Oxide Silicon Field Effect Transistor (MOSFET). The transistors of the sub-pixel circuit SPC may include an amorphous silicon semiconductor, a monocrystalline silicon semiconductor, polycrystalline silicon semiconductor, an oxide semiconductor, and the like.

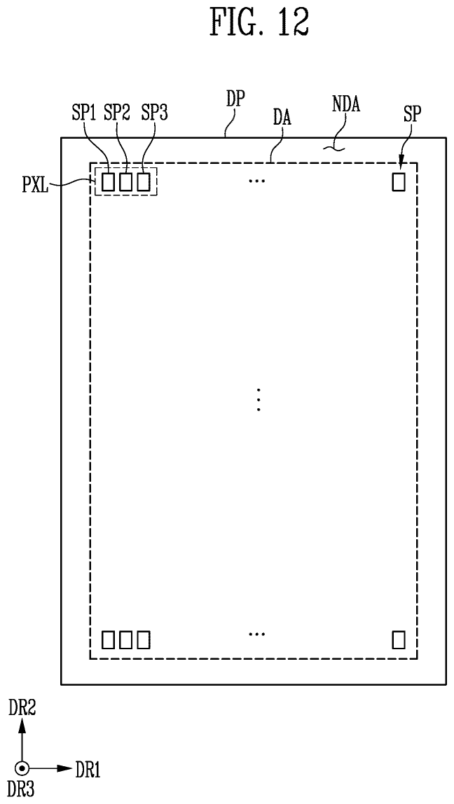

FIG. 12 is a schematic plan view illustrating the display panel constituting the display device shown in FIG. 10.

Referring to FIG. 12, the display panel DP may include a display area DA and a non-display area NDA. The display panel DP may display an image (or images) through the display area DA. The non-display area NDA may be disposed at the periphery of the display area DA. For example, the non-display area NDA may surround the display area DA.

The display panel DP may include sub-pixels SP in the display area DA. The sub-pixels SP may be arranged in a first direction DR1 and a second direction DR2 intersecting the first direction DR1. For example, the sub-pixels SP may be arranged in a matrix form in a first direction DR1 and a second direction DR2. In another example, the sub-pixels SP may be arranged in a zigzag form in the first direction DR1 and the second direction DR2. The arrangement of the sub-pixels SP may vary in some embodiments. The first direction DR1 may be a row direction, and the second direction DR2 may be a column direction.

Two or more sub-pixels among the sub-pixels SP may constitute one pixel PXL. As depicted in FIG. 12, it is illustrated that the pixel PXL includes three sub-pixels SP1, SP2, and SP3. However, embodiments are not limited thereto. For example, the pixel PXL may include two sub-pixels. Hereinafter, for convenience of description, it is assumed that the pixel PXL includes first to third sub-pixels SP1, SP2, and SP3.

Each of the first to third sub-pixels SP1, SP2, and SP3 may generate light of one of various colors such as red, green, blue, cyan, magenta, and yellow. Hereinafter, for clear and simple description, it is assumed that the first sub-pixel SP1 is to generate light of a red color, the second sub-pixel SP2 is to generate light of a green color, and the third sub-pixel SP3 is to generate light of a blue color.

Each of the first to third sub-pixels SP1, SP2, and SP3 may include at least one light emitting element to generate light. Light emitting elements of the first to third sub-pixels SP1, SP2, and SP3 may generate light of the same color. For example, the light emitting elements of the first to third sub-pixels SP1, SP2, and SP3 may generate light of a blue color. In other embodiments, the light emitting elements of the first to third sub-pixels SP1, SP2, and SP3 may generate lights of different colors. For example, the light emitting elements of the first to third sub-pixels SP1, SP2, and SP3 may generate lights a red color, a green color, and a blue color, respectively.

Self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines electrically connected to the sub-pixels SP, e.g., the first to mth gate lines GL1 to GLm, the first to nth data lines DL1 to DLn, the power lines PL, and the pixel control lines PXCL, which are shown in FIG. 10, may be disposed in the non-display area NDA.

At least one of the gate driver 120, the data driver 130, the voltage generator 140, and the controller 150, which are shown in FIG. 10, may be disposed in the non-display area NDA of the display panel DP. The gate driver 120 may be disposed in the non-display area NDA. The data driver 130, the voltage generator 140, and the controller 150 may be implemented into the driver integrated circuit DIC shown in FIG. 10, which is distinguished from the display panel DP, and the driver integrated circuit DIC may be electrically connected to the lines disposed in the non-display area NDA. In other embodiments, the gate driver 120, the data driver 130, the voltage generator 140, and the controller 150 may be implemented into one integrated circuit distinguished from the display panel DP.

The display area DA may have various shapes. The display area DA may have a closed-loop shape including linear sides and/or curved sides. For example, the display area DA may have shapes such as a polygon, a circle, a semicircle, and an ellipse.

The display panel DP may have a flat display surface. In other embodiments, the display panel DP may at least partially have a round display surface. The display panel DP may be bendable, foldable or rollable. The display panel DP and/or a substrate of the display panel DP may include materials having flexibility.

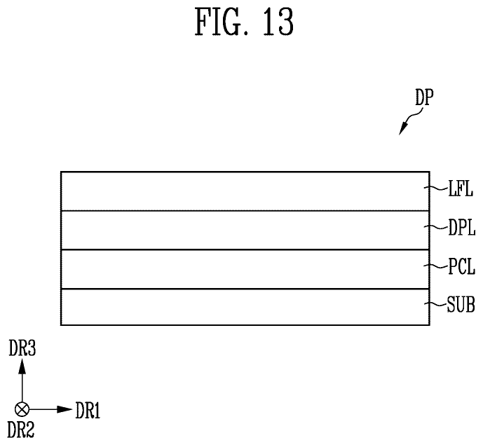

FIG. 13 is a schematic sectional view illustrating an embodiment of the display panel shown in FIG. 12.

Referring to FIG. 13, a display panel DP may include a substrate SUB, and a pixel circuit layer PCL, a display panel layer DPL, and a light functional layer LFL, which are sequentially stacked in a third direction DR3 intersecting the first and second directions DR1 and DR2 on the substrate SUB.

The substrate SUB may be made of an insulative material such as glass or resin. For example, the substrate SUB may include a glass substrate. In another example, the substrate SUB may include polyimide (PI) substrate. In still another example, the substrate SUB may include a silicon wafer substrate formed using a semiconductor process.

The substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like.

The circuit elements of the pixel circuit layer PCL may constitute a sub-pixel circuit SPC of each of the sub-pixels SP shown in FIG. 12. For example, the circuit elements of the pixel circuit layer PCL may be provided as transistors and one or more capacitors of the sub-pixel circuit SPC.

The lines of the pixel circuit layer PCL may include lines electrically connected to each of the sub-pixels SP. The lines of the pixel circuit layer PCL may include various signal lines and/or various voltage lines, which are desirable for driving the display panel layer DPL.

The display panel layer DPL may be disposed on the pixel circuit layer PCL. The display panel layer DPL may include light emitting elements of the sub-pixels SP.

The light functional layer LFL may be disposed on the display panel layer DPL. The light functional layer LFL may include light conversion patterns having color conversion particles and/or light scattering particles. For example, color conversion particles may include quantum dots. The quantum dots may change a wavelength (or color) of light emitted from the display panel layer DPL. The light functional layer LFL may further include light scattering patterns having light scattering particles. In another embodiment, the light conversion patterns and the light scattering patterns may be omitted.

The light functional layer LFL may further include a color filter layer including color filters. The color filter may allow light having a specific wavelength (or specific color) to be selectively transmitted therethrough. In another embodiment, the color filter layer may be omitted.

A window for protecting an exposed surface (or top surface) of the display panel DP may be provided on the light functional layer LFL. The window may protect the display panel DP from external impact (or force). The window may be bonded to the light functional layer LFL through an optically transparent adhesive (or cohesive) member. The window may have a multi-layer structure selected from a glass substrate, a plastic film, and a plastic substrate. This multi-layer structure may be formed through a continuous process or an adhesive process using an adhesive layer. The whole or a portion of the window may have flexibility.

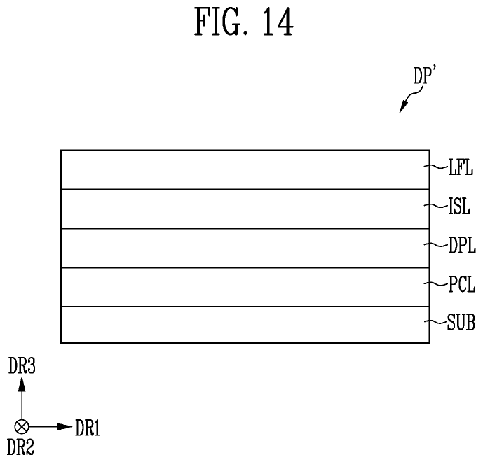

FIG. 14 is a schematic sectional view illustrating another embodiment of the display panel shown in FIG. 12.

Referring to FIG. 14, a display panel DP′ may include a substrate SUB, a pixel circuit layer PCL, a display panel layer DPL, an input sensing layer ISL, and a light functional layer LFL. The substrate SUB, the pixel circuit layer PCL, the display panel layer DPL, and the light functional layer LFL may be configured subsequently identical (or similar) to the substrate SUB, the pixel circuit layer PCL, the display panel layer DPL, and the light functional layer LFL, which are described with reference to FIG. 13, respectively. Therefore, descriptions of overlapping portions will be omitted.

The input sensing layer ISL may sense a user input with respect to a top surface (or display surface) of the display panel DP′. The input sensing layer ISL may include components suitable for sensing an external object such as a hand of a user or a pen. For example, the input sensing layer ISL may include touch electrodes.

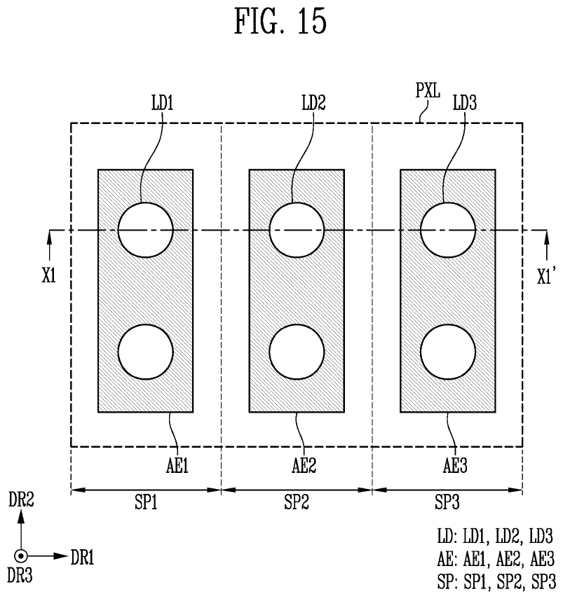

FIG. 15 is a schematic plan view illustrating an embodiment of any one pixel among the pixels included in the display panel shown in FIG. 12.

Referring to FIG. 15, a pixel PXL may include first to third sub-pixels SP1, SP2, and SP3. The first to third sub-pixels SP1, SP2, and SP3 may be arranged in the first direction DR1. However, the arrangement of the pixel PXL is not limited thereto, and may be variously changed in some embodiments. For example, the first to third sub-pixels SP1, SP2, and SP3 may be arranged in zigzag.

Each of first to third anode electrodes AE1, AE2, and AE3 may be disposed in each of the first to third sub-pixels SP1, SP2, and SP3, respectively. The first anode electrode AE1 may be provided as an anode electrode AE electrically connected to a sub-pixel circuit SPC (see FIG. 11) of the first sub-pixel SP1. The second anode electrode AE2 may be provided as an anode electrode AE electrically connected to a sub-pixel circuit SPC of the second sub-pixel SP2. The third anode electrode AE3 may be provided as an anode electrode AE electrically connected to a sub-pixel circuit SPC of the third sub-pixel SP3.

One or more first light emitting elements LD1, one or more second light emitting elements LD2, and one or more third light emitting elements LD3 may be disposed on the first to third anode electrodes AE1, AE2, and AE3. The first light emitting elements LD1 may be electrically connected to the first anode electrode AE1. The second light emitting elements LD2 may be electrically connected to the second anode electrode AE2. The third light emitting elements LD3 may be electrically connected to the third anode electrode AE3. In case that multiple light emitting elements are provided in each sub-pixel, each anode electrode may have a shape extending in a specific direction such as the second direction DR2, and light emitting elements electrically connected thereto may be arranged in the same direction.

The first light emitting elements LD1 may be provided as a light emitting element LD (shown in FIG. 11) included in the first sub-pixel SP1. The second light emitting elements LD2 may be provided as a light emitting element LD (shown in FIG. 11) included in the second sub-pixel SP2. The third light emitting elements LD3 may be provided as a light emitting element LD (shown in FIG. 11) included in the third sub-pixel SP3. In case that multiple light emitting elements are provided in one sub-pixel, multiple light emitting elements may be electrically connected in parallel between an anode electrode and a cathode electrode, to be provided as the light emitting element LD shown in FIG. 11.

Each of the first light emitting elements LD1, the second light emitting elements LD2, and the third light emitting elements LD3 may be similarly configured to the light emitting element LD which has been described with reference to FIGS. 1 to 4.

FIG. 16 is a schematic sectional view taken along line X1-X1′ shown in FIG. 15.

Referring to FIGS. 15 and 16, a pixel circuit layer PCL, a display panel layer DPL, and a light functional layer LFL may be sequentially disposed on a substrate SUB in the third direction DR3.

The pixel circuit layer PCL may include insulating layers, semiconductor patterns, and conductive patterns, which are stacked on the substrate SUB. The insulating layers may include a buffer layer BFL, one or more interlayer insulating layers ILD, and one or more passivation layers PSV1 and PSV2. The semiconductor patterns and the conductive patterns may be located between the insulating layers. The conductive patterns may include at least one material among copper (Cu), molybdenum (Mo), tungsten (W), aluminum neodymium (AlNd), titanium (Ti), aluminum (Al), and silver (Ag).

As described with reference to FIG. 11, the sub-pixel circuit SPC (see FIG. 11) of each of the first to third sub-pixels SP1, SP2, and SP3 may include transistors and one or more capacitors. The semiconductor patterns and the conductive patterns of the pixel circuit layer PCL may serve as the transistors and the capacitors of the sub-pixel circuit SPC. The conductive patterns of the pixel circuit layer PCL may further serve as lines, e.g., the first to mth gate lines GL1 to GLm, the first to nth data lines DL1 to DLn, the power lines PL, and the pixel control lines PXCL, which are shown in FIG. 10.

The buffer layer BFL may be disposed on one surface of the substrate SUB. The buffer layer BFL may prevent an impurity from being diffused into circuit elements and lines, which are included in the pixel circuit layer PCL. The buffer layer BFL may include an inorganic insulating layer including an inorganic material. The buffer layer BFL may include at least one of silicon nitride, silicon oxide, silicon oxynitride, and a metal oxide such as aluminum oxide. The buffer layer BFL may be provided as a single layer or a multi-layer. In case that the buffer layer BFL is provided as the multi-layer, layers of the multi-layer may be formed of the same material or be formed of different materials.

One or more barrier layers may be disposed between the substrate SUB and the buffer layer BFL. Each of the barrier layers may include polyimide.

First to third transistors T_SP1, T_SP2, and T_SP3 respectively corresponding to the first to third sub-pixels SP1, SP2, and SP3 may be disposed on the buffer layer BFL. The first transistor T_SP1 may be any one of transistors of a sub-pixel circuit SPC included in the first sub-pixel SP1. The second transistor T_SP2 may be any one of transistors of a sub-pixel circuit SPC included in the second sub-pixel SP2. The third transistor T_SP3 may be any one of transistors of a sub-pixel circuit SPC included in the third sub-pixel SP3. Each of the first to third transistors T_SP1, T_SP2, and T_SP3 may be understood as a transistor electrically connected to an anode electrode among transistors of a corresponding sub-pixel.

The first transistor T_SP1 may include a semiconductor pattern SCP, a gate electrode GE, a first terminal ET1, and a second terminal ET2. The first terminal ET1 may be any one of a source electrode and a drain electrode, and the second terminal ET2 may be the other of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact region in contact with the first terminal ET1 and a second contact region in contact with the second terminal ET2. A region between the first contact region and the second contact region may be a channel region. The channel region may overlap the gate electrode GE of the first transistor T_SP1 in the third direction DR3. The channel region is a semiconductor pattern substantially undoped with an impurity, and may be an intrinsic semiconductor. Each of the first contact region and the second contact region may be a semiconductor pattern doped with the impurity. For example, a p-type impurity may be used as the impurity, but embodiments are not limited thereto.

The semiconductor pattern SCP may include any one of various types of semiconductors, e.g., any one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. For example, the interlayer insulating layers ILD may be disposed on the buffer layer BFL. The interlayer insulating layers ILD may be inorganic insulating layers including an inorganic material. For example, each of the interlayer insulating layers ILD may include at least one of silicon nitride, silicon oxide, silicon oxynitride, and a metal oxide such as aluminum oxide. However, the interlayer insulating layers ILD are not limited thereto. For example, any one of the interlayer insulating layers ILD may include an organic insulating layer including an organic material.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP in the third direction DR3. The gate insulating layer GI may be provided (e.g., entirely provided) on the semiconductor pattern SCP and the buffer layer BFL to cover the semiconductor pattern SCP and the buffer layer BFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP. The gate electrode GE may be provided as a single layer including at least one material among copper (Cu), molybdenum (Mo), tungsten (W), aluminum neodymium (AlNd), titanium (Ti), aluminum (Al), and silver (Ag). The gate electrode GE may be provided as a multi-layer including at least one material among molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be in contact with the first and second contact regions of the semiconductor pattern SCP, respectively. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

The first transistor T_SP1 may be a low temperature poly-silicon transistor. However, embodiments are not limited thereto. For example, the first transistor T_SP1 may be an oxide semiconductor transistor. The sub-pixel circuit of the first sub-pixel SP1 may include different types of transistors. For example, the first transistor T_SP1 may be a low temperature poly-silicon transistor, and another transistor of the first sub-pixel SP1 may be an oxide semiconductor transistor. An oxide semiconductor of the corresponding oxide semiconductor transistor may be disposed on any one of the interlayer insulating layers ILD instead of an insulating layer on which the semiconductor pattern SCP of the first transistor T_SP1.

A case where the first transistor T_SP1 is a transistor having a top gate structure is described as an example. However, embodiments are not limited thereto. For example, the first transistor T_SP1 may be a transistor having a bottom gate structure. The structure of the first transistor T_SP1 may be variously changed.

Each of the second and third transistors T_SP2 and TSP3 may be identically configured to the first transistor T_SP1. Therefore, descriptions of overlapping portions will be omitted.

At least some of various lines of the display panel DP and/or the display device DD may be further disposed on the interlayer insulating layers ILD.

A first passivation layer PSV1 may be disposed over the interlayer insulating layers ILD and the first and second terminals ET1 and ET2. The passivation layer may be designated as a protective layer or a via layer. The first passivation layer PSV1 may protect components disposed under the first passivation layer PSV1 and provide a flat top surface.

First to third connection patterns CP1, CP2, and CP3 may be disposed on the first passivation layer PSV1. The first to third connection patterns CP1, CP2, and CP3 may be respectively electrically connected to first terminals ET1 of the first to third transistors T_SP1, T_SP2, and T_SP3 by penetrating the first passivation layer PSV1. The first to third connection patterns CP1, CP2, and CP3 may include at least one material among copper (Cu), molybdenum (Mo), tungsten (W), aluminum neodymium (AlNd), titanium (Ti), aluminum (Al), and silver (Ag).

At least some of various lines of the display panel DP and/or the display device DD may be further disposed on the first passivation layer PSV1.

A second passivation layer PSV2 may be disposed over the first to third connection patterns CP1, CP2, and CP3 and the first passivation layer PSV1. The second passivation layer PSV2 may protect components disposed under the second passivation layer PSV2, and provide a flat top surface.

Each of the first and second passivation layers PSV1 and PSV2 may include an inorganic insulating layer including an inorganic material and/or an organic insulating layer including an organic material. The inorganic insulating layer may include, for example, at least one of silicon oxide, silicon nitride, silicon oxynitride, and a metal oxide such as aluminum oxide. The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first and second passivation layers PSV1 and PSV2 may include the same material as any one of the interlayer insulating layers ILD, but embodiments are not limited thereto. Each of the first and second passivation layers PSV1 and PSV2 may be provided as a single layer, but be provided as a multi-layer.

The display panel layer DPL may be disposed on the second passivation layer PSV2. The display panel layer DPL may include first to third anode electrodes AE1, AE2, and AE3, a first bank BNK1, first to third light emitting elements LD1, LD2, and LD3, an overcoat layer OCL, a cathode electrode CE, and a capping layer CPL.

On the pixel circuit layer PCL, the first to third anode electrodes AE1, AE2, and AE3 may be disposed in the first to third sub-pixels SP1, SP2, and SP3, respectively.

The first anode electrode AE1 may be electrically connected to the first connection pattern CP1 through a contact hole penetrating the second passivation layer PSV2. The second anode electrode AE2 may be electrically connected to the second connection pattern CP2 through another contact hole penetrating the second passivation layer PSV2. The third anode electrode AE3 may be electrically connected to the third connection pattern CP3 through still another contact hole penetrating the second passivation layer PSV2. As such, the first to third anode electrodes AE1, AE2, and AE3 may be electrically connected to the first to third transistors T_SP1, T_SP2, and T_SP3, respectively.

The first bank BNK1 may be disposed on the first to third anode electrodes AE1, AE2, and AE3. The first bank BNK1 may have first openings OP1 exposing portions of the first to third anode electrodes AE1, AE2, and AE3. The first to third light emitting elements LD1, LD2, and LD3 may be disposed in the first openings OP1 of the first bank BNK1. As such, the first bank BNK1 may be provided as a pixel defining layer defining areas in which the first to third light emitting elements LD1, LD2, and LD3 are located.

The first bank BNK1 may include a light blocking material to prevent light mixture between adjacent sub-pixels. The first bank BNK1 may include an organic material. For example, the first bank BNK1 may include an organic insulating material such as acrylic resin, epoxy resin, phenolic resin, polyamide resin, or polyimide resin. In order to further improve light emission efficiency, a reflective layer including a reflective material may be further disposed on side surfaces of the first bank BNK1, which are adjacent to the first openings OP1.

The first to third light emitting elements LD1, LD2, and LD3 may be disposed on the first to third anode electrodes AE1, AE2, and AE3, respectively. The first to third light emitting elements LD1, LD2, and LD3 may be bonded to the first to third anode electrodes AE1, AE2, and AE3, respectively. Each of the first to third light emitting elements LD1, LD2, and LD3 may be similarly configured to the light emitting element LD which has been described with reference to FIGS. 1 to 4. Therefore, descriptions of overlapping portions will be omitted.

A bonding electrode BDE of the first light emitting element LD1 may be electrically connected to the first anode electrode AE1. A bonding electrode BDE of the second light emitting element LD2 may be electrically connected to the second anode electrode AE2. A bonding electrode BDE of the third light emitting element LD3 may be electrically connected to the third anode electrode AE3. Top surfaces of second semiconductor layers 30 of the first to third light emitting elements LD1, LD2, and LD3 may be electrically connected to the cathode electrode CE. Accordingly, the first light emitting element LD1 may be electrically connected between the first anode electrode AE1 and the cathode electrode CE, the second light emitting element LD2 may be electrically connected between the second anode electrode AE2 and the cathode electrode CE, and the third light emitting element LD3 may be electrically connected between the third anode electrode AE3 and the cathode electrode CE.

The overcoat layer OCL may be disposed in the first openings OP1 in which the first to third light emitting elements LD1, LD2, and LD3 are disposed. The overcoat layer OCL may fix the first to third light emitting elements LD1, LD2, and LD3 bonded to the first to third anode electrodes AE1, AE2, and AE3 not to move. The overcoat layer OCL may protect components disposed under the overcoat layer OCL from a foreign matter such as dust or moisture. The overcoat layer OCL may include at least one of an inorganic insulating layer and an organic insulating layer. For example, the overcoat layer OCL may include epoxy, but embodiments are not limited thereto.

The overcoat layer OCL may not be disposed on a top surface of each of the first to third light emitting elements LD1, LD2, and LD3. The first to third light emitting elements LD1, LD2, and LD3 may protrude to the light functional layer LFL. The first to third light emitting elements LD1, LD2, and LD3 may be at least partially located in second openings OP2 of a second bank BNK2. For example, a height of the top surface of each of the first to third light emitting elements LD1, LD2, and LD3 from the substrate SUB may be higher than a height of a lowermost end of a reflective layer RFL from the substrate SUB. Accordingly, light emitted from the first to third light emitting elements LD1, LD2, and LD3 may be provided to the light functional layer LFL at a relatively high ratio.

The cathode electrode CE may be disposed on the first to third light emitting elements LD1, LD2, and LD3. The cathode electrode CE may be disposed (e.g., entirely disposed) on the first bank BNK1, the first to third light emitting elements LD1, LD2, and LD3, and the overcoat layer OCL. The cathode electrode CE may be in contact with the top surface of the second semiconductor layer 20 of each of the first to third light emitting elements LD1, LD2, and LD3. The cathode electrode CE may be electrically connected to the second power voltage node VSSN shown in FIG. 11. The second power voltage applied to the second power voltage node VSSN may be transferred to the first to third light emitting elements LD1, LD2, and LD3 through the cathode electrode CE.

The cathode electrode CE may be formed substantially transparent or translucent to satisfy a predetermined light transmittance. The cathode electrode CE may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the cathode CE is not limited thereto.

The capping layer CPL may be disposed on the cathode electrode CE. The capping layer CPL may protect components disposed under the capping layer CPL such as the cathode electrode CE and the first to third light emitting elements LD1, LD2, and LD3, from external moisture, humidity, and the like. The capping layer CPL may include at least one of silicon nitride, silicon oxide, silicon oxynitride, and a metal oxide such as aluminum oxide. However, the material of the capping layer CPL is not limited thereto.

The light functional layer LFL may be disposed on the capping layer CPL. The light functional layer LFL may include the second bank BNK2, the reflective layer RFL, a third passivation layer PSV3, first and second light conversion patterns CCP1 and CCP2, a light scattering pattern LSP, a low refractive layer LRL, and a color filter layer CFL.

The second bank BNK2 may be disposed on the capping layer CPL. The second bank BNK2 may overlap the first bank BNK1 in the third direction DR3. The second bank BNK2 may have the second openings OP2 overlapping the first openings OP1.

The second bank BNK2 may include a light blocking material to prevent light mixture between adjacent sub-pixels and the first to third sub-pixels SP1, SP2, and SP3. The second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the second openings OP2. The reflective layer RFL is to reflect incident light, and accordingly, light emission efficiency can be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

It may be understood that emission areas EMA and a non-emission areas NEMA of the first to third sub-pixels SP1, SP2, and SP3 may be defined by the second bank BNK2. For example, each of the emission areas EMA may be spaced apart from each other with respect to each of the non-emission areas NEMA in the first direction DR1. An area overlapping the second bank BNK2 may correspond to the non-emission area NEMA in the third direction DR3. Areas overlapping the second openings OP2 of the second bank BNK2 may correspond to the emission areas EMA in the third direction DR3.

On a capping layer CPL, the third passivation layer PSV3 may be disposed in the second openings OP2. The third passivation layer PSV3 may protect components disposed under the third passivation layer PSV3, and provide a flat top surface. The third passivation layer PSV3 may include the same material as any one of the first and second passivation layers PSV1 and PSV2, but embodiments are not limited thereto.

On the third passivation layer PSV3, the first and second light conversion patterns CCP1 and CCP2 and the light scattering pattern LSP may be disposed in the second openings OP2.

The first and second light conversion patterns CCP1 and CCP2 and the light scattering pattern LSP may include color conversion particles and/or light scattering particles. The color conversion particles may convert incident light into light of another color by changing a wavelength of the incident light. Also, the color conversion particles may scatter incident light. The color conversion particles may be quantum dots. The light scattering particles may scatter incident light.

The first to third light emitting elements LD1, LD2, and LD3 may emit light of a blue color. The first light conversion pattern CCP1 may include first color conversion particles QD1 to convert light of the blue color into light of a red color. The second light conversion pattern CCP2 may include second color conversion particles QD2 to convert light of the blue color into light of a green color. The light scattering pattern LSP may include light scattering particles SCT which scatter light of the blue color so as to improve light emission efficiency. Accordingly, the first to third sub-pixels SP1, SP2, and SP3 may be provided as a red sub-pixel, a green sub-pixel, and a blue sub-pixel, respectively. At least one of the first and second light conversion patterns CCP1 and CCP2 and the light scattering pattern LSP may further include color conversion patterns which convert light of the blue color into light of a white color.

The first to third light emitting elements LD1, LD2, and LD3 may emit lights of the red color, the green color, and the blue color, respectively. Each of the first and second light conversion patterns CCP1 and CCP2 and the light scattering pattern LSP may include the light scattering particles SCT. As such, the particles included in the first and second light conversion patterns CCP1 and CCP2 and the light scattering pattern LSP may be variously changed according to colors of lights emitted from the first to third light emitting elements LD1, LD2, and LD3.

In another embodiment, the first and second light conversion patterns CCP1 and CCP2 and the light scattering pattern LSP may be omitted.

The low refractive layer LRL may be disposed on the second bank BNK2, the reflective layer RFL, the first and second light conversion patterns CCP1 and CCP2, and the light scattering pattern LSP. The low refractive layer LRL may have a refractive index lower than a refractive index of each of the first and second light conversion patterns CCP1 and CCP2 and the light scattering pattern LSP. The low refractive layer LRL is to refract or totally reflect light according to an incident angle of the corresponding light. The low refractive layer LRL may again provide light passing through the first and second light conversion patterns CCP1 and CCP2 and the light scattering pattern LSP to the first and second light conversion patterns CCP1 and CCP2 and the light scattering pattern LSP, and accordingly, the light conversion efficiency and light scattering efficiency of the first and second light conversion patterns CCP1 and CCP2 and the light scattering pattern LSP can be improved. The low refractive layer LRL may be omitted in an area corresponding to the third sub-pixel SP3.

The color filter layer CFL may be disposed on the low refractive layer LRL. The color filter layer CFL may include the first to third color filters CF1, CF2, and CF3 and light blocking patterns LBP.

The first to third color filters CF1, CF2, and CF3 may overlap the first and second light conversion patterns CCP1 and CCP2 and the light scattering pattern LSP, respectively. Each of the first to third color filters CF1, CF2, and CF3 may allow light in a desired wavelength range to be selectively transmitted therethrough. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1, CF2, and CF3 may have a refractive index higher than the refractive index of the low refractive layer LRL. However, embodiments are not limited thereto, and the first to third color filters CF1, CF2, and CF3 may have a refractive index lower than or equal to the refractive index of the low refractive layer LRL.

The light blocking patterns LBP may be disposed between the color filters CF1, CF2, and CF3. It may be understood that the emission areas (or light output areas) EMA and the non-emission area NEMA of the first and second sub-pixels SP1, SP2, and SP3 are defined by the light blocking patterns LBP. An area overlapping the light blocking patterns LBP may correspond to the non-emission area NEMA in the third direction DR3. Areas not overlapping the light blocking patterns LBP may correspond to the emission areas EMA in the third direction DR3.

The light blocking patterns LBP may include at least one of various kinds of light blocking materials. Each of the light blocking patterns LBP may be provided in the form of a multi-layer overlapping at least two color filters among the first to third color filters CF1, CF2, and CF3. For example, each of the light blocking patterns LBP may be formed as the first to third color filters CF1, CF2, and CF3 overlap each other. In another example, a light blocking pattern between the first and second color filters CF1 and CF2 among the light blocking patterns LBP may be formed as a multi-layer in which the first and second color filters CF1 and CF2 overlap each other, and a light blocking pattern between the second and third color filters CF2 and CF3 among the light blocking patterns LBP may be formed as a multi-layer in which the second and third color filters CF2 and CF3 overlap each other. A light blocking pattern between the first color filter CF1 and a third color filter CF3 of an adjacent pixel may be formed as a multi-layer in which the first and third color filters CF1 and CF3 overlap each other. As such, each of the first to third color filters CF1, CF2, and CF3 may extend to the non-emission area NEMA to form the light blocking patterns LBP.

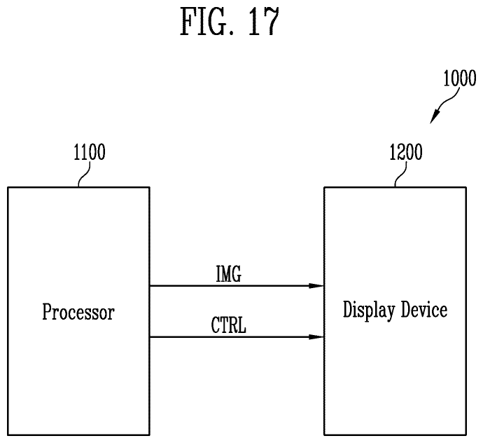

A display system to which the above-described display device is applied will be described with reference to FIGS. 17 to 21.

FIG. 17 is a schematic block diagram illustrating a display system in accordance with an embodiment of the disclosure.

Referring to FIG. 17, the display system 1000 may include a processor 1100 and a display device 1200.

The processor 1100 may perform various tasks and various calculations. The processor 1100 may include an Application Processor (AP), a Graphics Processing Unit (GPU), a microprocessor, a Central Processing Unit (CPU), and the like. The processor 1100 may be electrically connected to other components of the display system 1000 through a bus system to control the components of the display system 1000.

The processor 1100 may transmit image data IMG and a control signal CTRL to the display device 1200. The display device 1200 may display an image (or images) based on the input image data IMG and the control signal CTRL. The display device 1200 may be configured identical to the display device DD described with reference to FIG. 1. The input image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

In other embodiments, the display system 1000 shown in FIG. 17 may be applied to, a mobile phone, a smartphone, a portable computer, a tablet personal computer (PC), a watch phone, a portable multimedia player (PMP), a navigation system, an ultra-mobile computer (UMPC), a virtual reality (VR) device, a mixed reality (MR) device, and an augmented reality (AR) device.

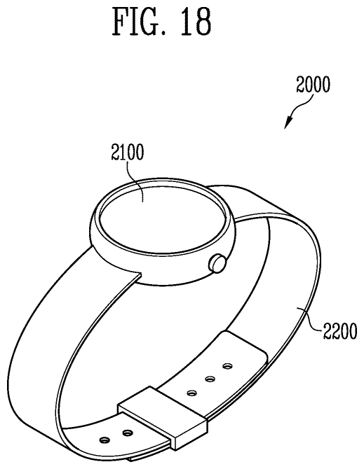

FIGS. 18 to 21 are schematic perspective views illustrating application examples of the display system.

Referring to FIG. 18, the display system 1000 shown in FIG. 17 may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The display system 1000 and/or the display device 1200 may be applied to the display part 2100 so that image data including time information can be provided to the user.

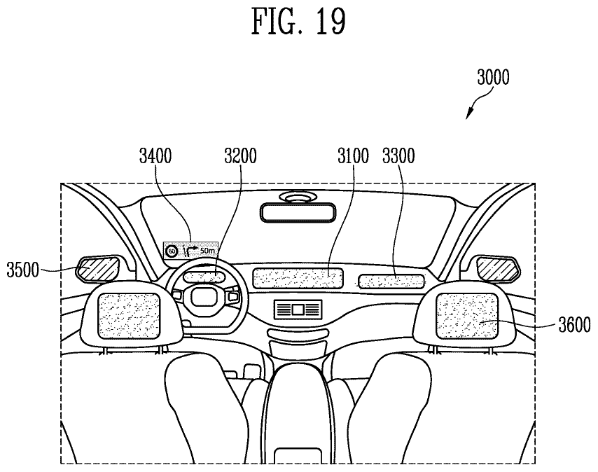

Referring to FIG. 19, the display system 1000 shown in FIG. 17 may be applied to an automotive display system 3000. The automotive display system 3000 may include a computing system provided at the inside/outside of a vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear seat display 3600, which are provided in the vehicle.

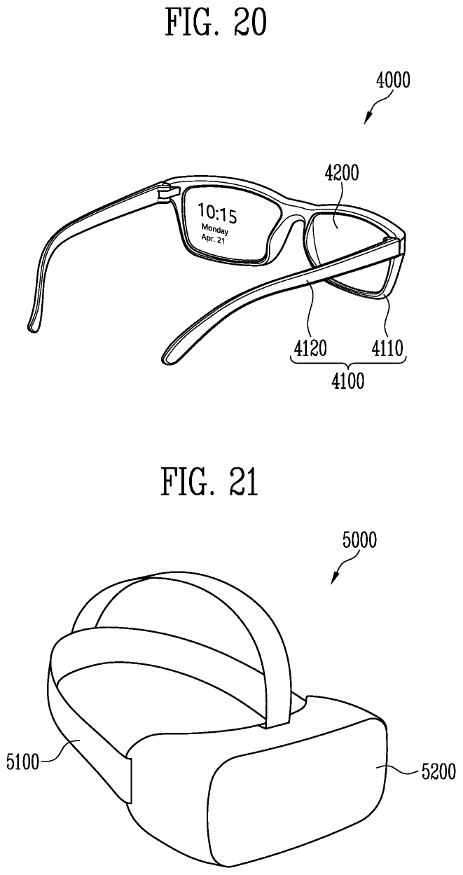

Referring to FIG. 20, the display system 1000 shown in FIG. 17 may be applied to smart glasses 4000. The smart glasses 4000 are a wearable electronic device which can be worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge to be folded or unfolded with respect to the housing 4110.

A battery, a touch pad, a microphone, a camera, and the like may be built in the frame 4100. A projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, transparent synthetic resin, and the like.

In order to enable eyes of the user to recognize visual information, the lens part 4200 may allow an image caused by a light signal transmitted from the projector of the frame 4100 to be reflected by a rear surface (e.g., a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

Referring to FIG. 21, the display system 1000 shown in FIG. 17 may be applied to a head mounted display device 5000.

The head mounted display device 5000 may be a wearable electronic device which can be worn on the head of a user. For example, the head mounted display device 5000 may be a wearable device for virtual reality (VR) or mixed reality (MR).

The head mounted display device 5000 may include a head mounted band 5100 and a display accommodating case 5200. The head mounted band 5100 may be electrically connected to the display accommodating case 5200. The head mounted band 5100 may include a horizontal band and/or a vertical band, used to fix the head mounted display device 5000 to the head of the user. The horizontal band may surround a side portion of the head of the user, and the vertical band may surround an upper portion of the head of the user. However, embodiments are not limited thereto. For example, the head mounted band 5100 may be implemented in the form of a glasses frame, a helmet or the like.

The display device accommodating case 5200 may accommodate the display system 1000 and/or the display device 1200.

The disclosure will be described in more detail through specific embodiments. However, the following embodiments are merely examples for helping understanding of the disclosure, but the scope of the disclosure is not limited thereto. It will be readily understood by those skilled in the art that various changes and modifications can be made thereto within the technical spirit and scope of the disclosure. It is also apparent that the modifications and changes fall within the scope of the disclosure defined by the appended claims.

### EMBODIMENTS & COMPARATIVE EXAMPLES

### Embodiment 1

The light emitting element LD which has been described with reference to FIGS. 1 and 2 is manufactured. A gallium nitride (GaN) semiconductor material doped with a p-type dopant is used for the first semiconductor layer 10, and a gallium nitride (GaN) semiconductor material doped with an n-type dopant is used for the second semiconductor layer 20. A material ordinarily used in the art is used for the active layer 30 and the bonding electrode BDE. Silicon oxide may be used for the second insulative film IIL2.

A first insulative film IIL1 may be formed through an atomic layer deposition process (see FIGS. 7 and 8) using a Group IV element-amine-based compound precursor and a precursor for providing oxygen at a film formation temperature of about 80° C. For example, tris(dimethylamino)cyclopentadienyl zirconium is used as the Group IV element-amine-based compound precursor.

### Embodiment 2

In the Embodiment 2, the light emitting element LD which has been described with reference to FIGS. 1 and 2 is manufactured identically to the Embodiment 1, except that an atomic layer deposition process of forming a first insulative film IIL1 is performed at a film formation temperature of about 150° C.

### Embodiment 3

In the Embodiment 3, the light emitting element LD which has been described with reference to FIGS. 1 and 2 is manufactured identically to the Embodiment 1, except that tris(dimethylamino)cyclopentadienyl zirconium is used as the Group IV element-amine-based compound precursor in an atomic layer deposition process of forming a first insulative film IIL1.

### Embodiment 4

In the Embodiment 4, the light emitting element LD which has been described with reference to FIGS. 1 and 2 is manufactured identically to the Embodiment 3, except that an atomic layer deposition process of forming a first insulative film IIL1 is performed at a film formation temperature of about 150° C.

### Comparative Example 1

In the Comparative Example 1, the light emitting element LD which has been described with reference to FIGS. 1 and 2 is manufactured identically to the Embodiment 1, except that an atomic layer deposition process of forming a first insulative film IIL1 is performed at a film formation temperature of about 250° C.

### Comparative Example 2

In the Comparative Example 2, the light emitting element LD which has been described with reference to FIGS. 1 and 2 is manufactured identically to the Embodiment 3, except that an atomic layer deposition process of forming a first insulative film IIL1 is performed at a film formation temperature of about 250° C.

### Experimental Example 1: XPS Spectrum Analysis

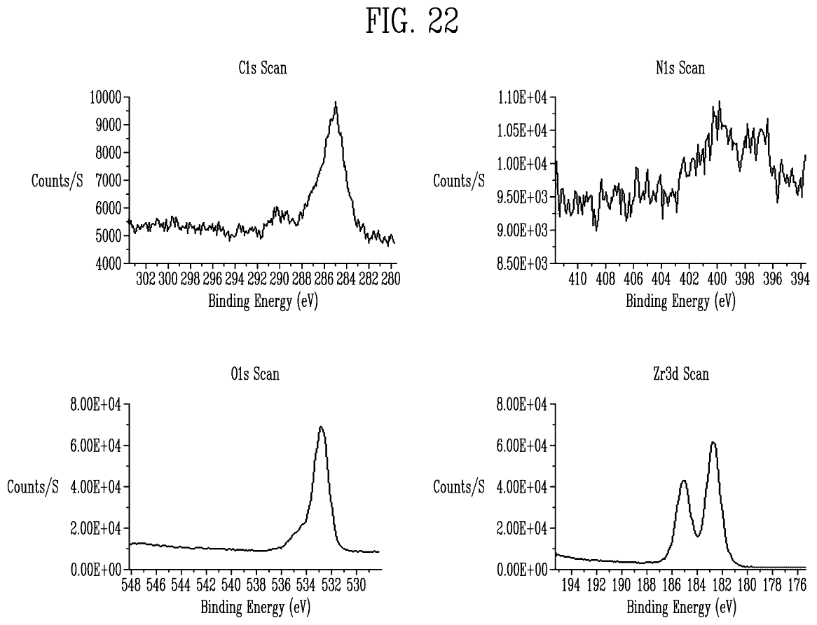

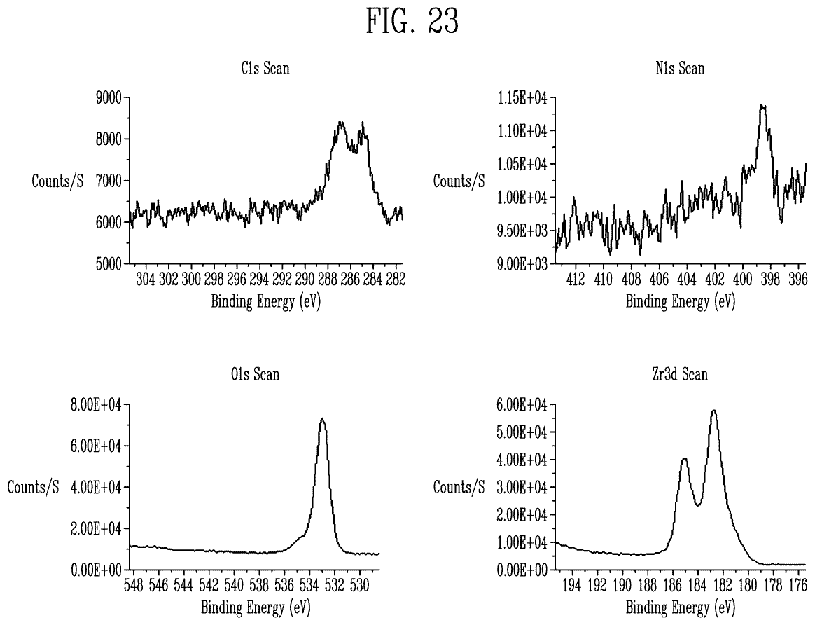

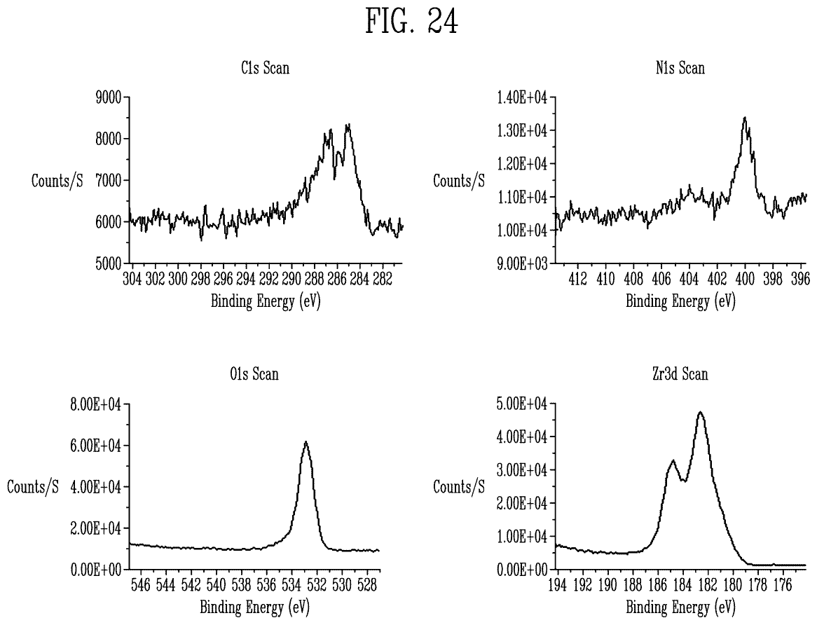

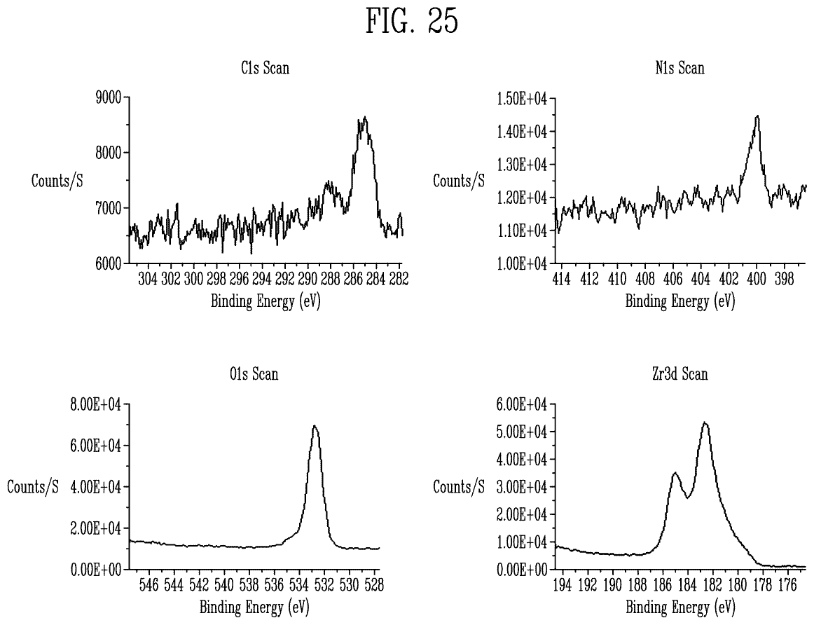

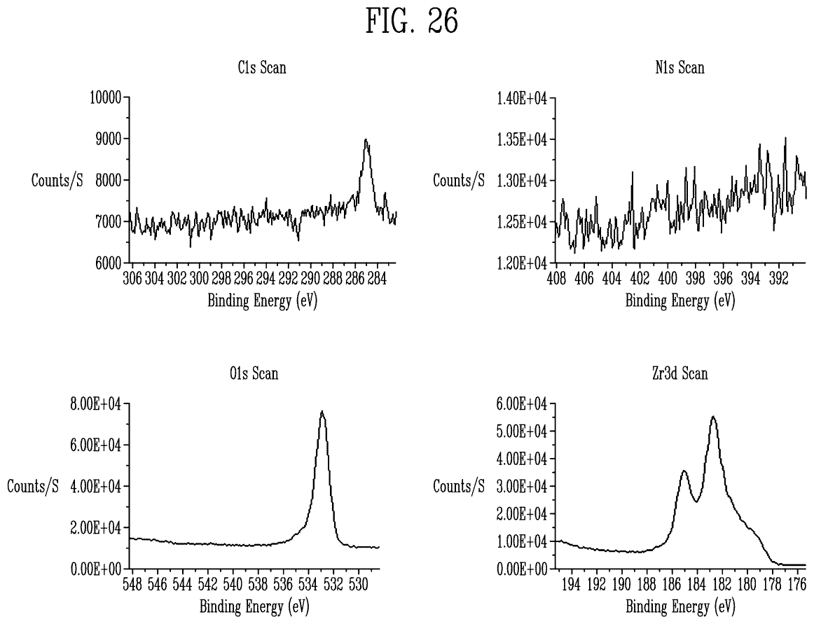

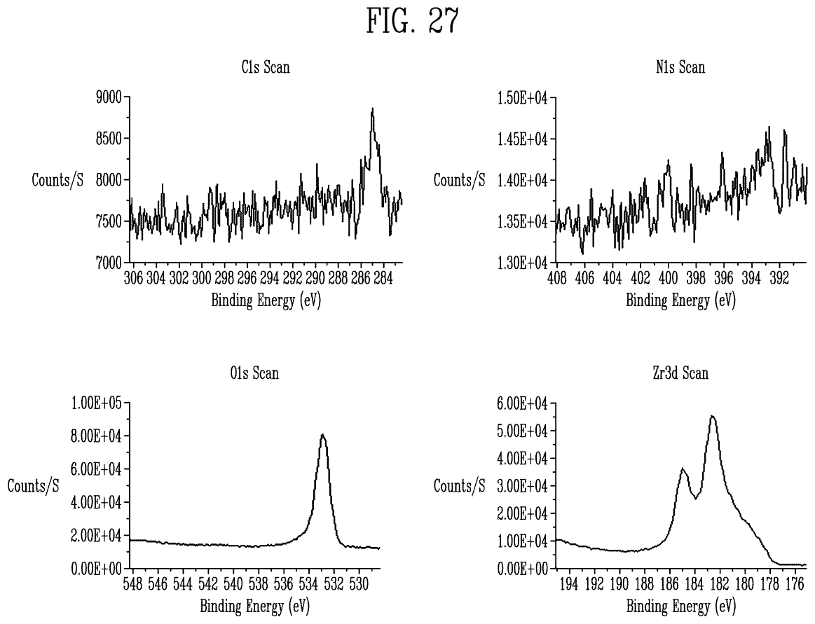

XPS results of the first insulative films IIL1 of the Embodiments 1 to 4 and the Comparative Examples 1 and 2 are illustrated. FIG. 22 illustrates schematic graphs showing an XPS result of the first insulative film IIL1 of the Embodiment 1. FIG. 23 illustrates schematic graphs showing an XPS result of the first insulative film IIL1 of the Embodiment 2. FIG. 24 illustrates schematic graphs showing an XPS result of the first insulative film IIL1 of the Embodiment 3. FIG. 25 illustrates schematic graphs showing an XPS result of the first insulative film ILL1 of the Embodiment 4. FIG. 26 illustrates schematic graphs showing an XPS result of the first insulative film IIL1 of the Comparative Example 1. FIG. 27 illustrates schematic graphs showing an XPS result of the first insulative film IIL1 of the Comparative Example 2. In each of FIGS. 22 to 27, XPS profiles of a carbon atom (C1s), a nitrogen atom (N1s), an oxygen atom (O1s), and a zirconium atom (Zr3d) are illustrated.

A content ratio (unit: Atomic %) for each atom, which is yielded by analyzing each of spectra of the first insulative films IIL1 of the Embodiments 1 to 4 and the Comparative examples 1 and 2 is illustrated in the following Table 1.

TABLE 1

| | Atomic % | | | | Ratio | |
|---|---|---|---|---|---|---|
| | C1s | N1s | O1s | Zr3d | [N]/[Zr] | [C]/[Zr] |
| Embodiment 1 | 24.4 | 5.7 | 49.9 | 20.2 | 0.28 | 1.20 |
| Embodiment 2 | 17.6 | 4.4 | 53.4 | 24.6 | 0.18 | 0.71 |
| Embodiment 3 | 19.1 | 7.2 | 49.2 | 25.1 | 0.29 | 0.76 |
| Embodiment 4 | 13.5 | 6.1 | 52.5 | 27.8 | 0.22 | 0.49 |
| Comparative | 9.9 | 2.3 | 57.8 | 29.9 | 0.08 | 0.33 |
| example 1 | | | | | | |
| Comparative | 8.0 | 2.3 | 59.0 | 30.8 | 0.08 | 0.26 |
| example 2 | | | | | | |

Referring to the Table 1, a content ratio of nitrogen:Group IV element (Zr) in the first insulative film IIL1 of the Embodiment 1 is about 0.28:1, a content ratio of nitrogen:Group IV element (Zr) in the first insulative film IIL1 of the Embodiment 2 is about 0.18:1, a content ratio of nitrogen:Group IV element (Zr) in the first insulative film IIL1 of the Embodiment 3 is about 0.29:1, and a content ratio of nitrogen:Group IV element (Zr) in the first insulative film IIL1 of the Embodiment 4 is about 0.22:1.

A content ratio of nitrogen:Group IV element (Zr) in the first insulative film IIL1 of the Comparative Example 1 is about 0.08:1, and a content ratio of nitrogen:Group IV element (Zr) in the first insulative film IIL1 of the Comparative Example 2 is about 0.08:1.

### Experimental Example 2: Luminance Analysis

The light emitting element LD of the Embodiments 2 to 4 and the Comparative Example 2 is driven at a current density about 12 A/cm², External Quantum Efficiencies (EQEs) just after the driving of the light emitting element LD is started were measured, and measurement results were illustrated in the following Table 2.

TABLE 2

| | EQE [%] |
|---|---|
| Embodiment 2 | 21.22 ± 0.20 |
| Embodiment 3 | 21.96 ± 0.46 |
| Embodiment 4 | 21.84 ± 0.49 |
| Comparative example 2 | 19.44 ± 0.49 |

Referring to the Table 2, it can be seen that the light emitting element LD of the Embodiments 2 to 4 exhibits an excellent EQE as compared with the light emitting element LD of the Comparative Example 2.

### Experimental Example 3: Luminance Maintenance Ratio Analysis

The light emitting element LD of the Embodiments 1 to 4 and the Comparative Examples 1 and 2 is driven at a current density about 50 A/cm² for about 300 hours. A ratio of a luminance of the light emitting element LD after driving for about 300 hours with respect to a luminance of the light emitting element LD in initial driving is defined as a luminance maintenance ratio, luminance maintenance ratios of the Embodiments 1 to 4 and the Comparative Examples 1 and 2 were measured, and measurement results were illustrated in the following Table 3.

TABLE 3

| | Luminance maintenance ratio [%] |
|---|---|
| Embodiment 1 | 90 |
| Embodiment 2 | 85 |
| Embodiment 3 | 90 |
| Embodiment 4 | 85 |
| Comparative example 1 | 70 |
| Comparative example 2 | 70 |

Referring to the Table 3, it can be seen that the light emitting element LD of the Embodiments 1 to 4 have excellent luminance maintenance ratios in driving for a long period of time, as compared with the light emitting element LD of the Comparative Examples 1 and 2.

In the light emitting element in accordance with the disclosure, the nitrogen-containing Group IV element oxide include in the first insulative film can perform a function of suppressing nitrogen vacancy formation at surfaces of the first and second semiconductor layers including a metal nitride. Accordingly, the efficiency of the light emitting element can be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A light emitting element comprising:
a light emitting stack member including a first semiconductor layer including a metal nitride doped with a dopant having a first conductivity type, a second semiconductor layer including a metal nitride doped with a dopant having a second conductivity type opposite to the first conductivity type, and an active layer disposed between the first semiconductor layer and the second semiconductor layer; and
a first insulative film covering at least a portion of an outer circumferential surface of the light emitting stack member,
wherein the first insulative film includes a nitrogen-containing Group IV element oxide, and
in the nitrogen-containing Group IV element oxide, a content ratio of nitrogen:Group IV element is in a range of about 0.1:1 and about 1:1, based on a unit (atomic %).

2. The light emitting element of claim 1, wherein the first insulative film is in direct contact with at least one of the first semiconductor layer and the second semiconductor layer.

3. The light emitting element of claim 2, wherein the first insulative film covers all side surfaces of the first and second semiconductor layers, which define a side surface of the light emitting stack member.

4. The light emitting element of claim 1, wherein the nitrogen-containing Group IV element oxide further includes carbon (C).

5. The light emitting element of claim 4, wherein, in the nitrogen-containing Group IV element oxide, a content ratio of carbon:Group IV element is in a range of about 0.01:1 to about 1.3:1, based on a unit (atomic %).

6. The light emitting element of claim 1, wherein, in the nitrogen-containing Group IV element oxide, a content ratio of oxygen:Group IV element is in a range of about 1.5:1 to about 2.5:1, based on a unit (atomic %).

7. The light emitting element of claim 1, wherein a Group IV element included in the nitrogen-containing Group IV element oxide is zirconium (Zr) or hafnium (Hf).

8. The light emitting element of claim 1, further comprising a second insulative film covering the first insulative film.

9. The light emitting element of claim 8, wherein at least the first insulative film is disposed between the second insulative film and the light emitting stack member.

10. The light emitting element of claim 8, wherein the second insulative film includes at least one selected from the group consisting of silicon oxide, silicon nitride, silicon oxynitride, aluminum oxide, and titanium oxide.

11. A method of manufacturing a light emitting element, the method comprising:
forming a first insulative film covering at least a portion of an outer circumferential surface of a light emitting stack member,
wherein the light emitting stack member includes a first semiconductor layer including a metal nitride doped with a dopant having a first conductivity type, a second semiconductor layer including a metal nitride doped with a dopant having a second conductivity type opposite to the first conductivity type, and an active layer disposed between the first semiconductor layer and the second semiconductor layer,
the first insulative film includes a nitrogen-containing Group IV element oxide, and
in the nitrogen-containing Group IV element oxide, a content ratio of nitrogen:Group IV element is in a range of about 0.1:1 to about 1:1, based on a unit (atomic %).

12. The method of claim 11, wherein the first insulative film is formed through an atomic layer deposition process using a Group IV element-amine-based compound precursor represented by the following Chemical Formula 1: 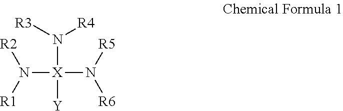
in the Chemical Formula 1, each of R1 to R6 is independently hydrogen or an alkyl group of C1 to C2, and R1 to R6 cannot all be hydrogen,
X is a Group IV element, and
Y is an amino group, an amine group in which at least one of hydrogen atoms of the amino group is replaced with an alkyl group of C1 to C2, or an aryl group of C5 to C6.

13. The method of claim 12, wherein the X is zirconium (Zr) or hafnium (Hf).

14. The method of claim 12, wherein the Chemical Formula 1 is represented by the following Chemical Formula 2 or the following Chemical Formula 3: 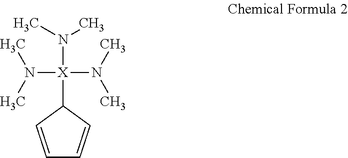
in the Chemical Formula 2, X is a Group IV element, and 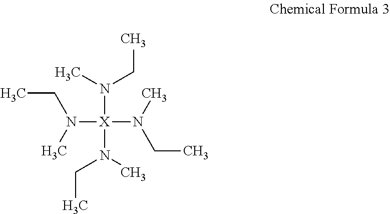
in the Chemical Formula 3, X is a Group IV element.

15. The method of claim 12, wherein the atomic layer deposition process is performed in a range of about 50° C. to about 200° C.

16. The method of claim 11, wherein the first insulative film is in direct contact with at least one of the first semiconductor layer and the second semiconductor layer.

17. The method of claim 16, wherein the first insulative film covers all side surfaces of the first and second semiconductor layers, which define a side surface of the light emitting stack member.

18. An electronic device comprising:
a display device including a light emitting element disposed on a substrate,
wherein the light emitting element includes:
a light emitting stack member including a first semiconductor layer including a metal nitride doped with a dopant having a first conductivity type, a second semiconductor layer including a metal nitride doped with a dopant having a second conductivity type opposite to the first conductivity type, and an active layer disposed between the first semiconductor layer and the second semiconductor layer; and
a first insulative film covering at least a portion of an outer circumferential surface of the light emitting stack member,
the first insulative film includes a nitrogen-containing Group IV element oxide, and
in the nitrogen-containing Group IV element oxide, a content ratio of nitrogen:Group IV element is in a range of about 0.1:1 to about 1:1, based on a unit (atomic %).

19. The electronic device of claim 18, wherein the electronic device is at least one of a smart watch, a mobile phone, a smartphone, a portable computer, a tablet personal computer (PC), a watch phone, an automotive display, a smart glass, a portable multimedia player (PMP), a navigation system, an ultra-mobile computer (UMPC), a head mounted display (HMD) device, a virtual reality (VR) device, a mixed reality (MR) device, and an augmented reality (AR) device.
